(19) United States
(12) Patent Application Publication
(10) Pub. No.: US 2026/0068572 A1
(43) Pub. Date: Mar. 5, 2026

(54) WAFER GRINDING APPARATUS AND WAFER GRINDING METHOD

(71) Applicant: DISCO CORPORATION, Tokyo (JP)

(72) Inventors: Atsushi INOUE, Tokyo (JP); Kosuke ABE, Tokyo (JP); Taesup YOO, Tokyo (JP); Yusuke SATO, Tokyo (JP); Masahiro TAKEKAWA, Tokyo (JP); Yuto TAKAGI, Tokyo (JP); Yohei WAKABAYASHI, Tokyo (JP)

(73) Assignee: DISCO CORPORATION, Tokyo (JP)

(21) Appl. No.: 19/316,133

(22) Filed: Sep. 2, 2025

(30) Foreign Application Priority Data
Sep. 5, 2024 (JP) 2024-153376
Sep. 13, 2024 (JP) 2024-159268
Jun. 11, 2025 (JP) 2025-097791

(51) Int. Cl. H01L 21/304; H01L 21/67; H01L 21/687

(52) U.S. Cl. CPC H01L 21/304

(57) ABSTRACT

A grinding apparatus for grinding a wafer includes a chuck table, a grinding unit, an elevating mechanism, a grinding water supply device, a spray nozzle, a thickness measuring device, and a controller to control spraying water from a spray nozzle toward the wafer so as to expand or contract the chuck table via the wafer and thereby changing a height of a holding surface such that warm water is sprayed toward a position, of which thickness value among thickness values measured by the thickness measuring device indicates a thickness greater than a preset target thickness, or a position, of which thickness value indicates a thickness greater than an average value of the thickness values; or cold water is sprayed toward a position, of which thickness value indicates a thickness less than the preset target thickness, or a position, of which thickness value indicates a thickness less than the average value.

### CROSS REFERENCE TO RELATED APPLICATIONS

This application is based upon and claims the benefit of priority from the prior Japanese Patent Applications No. 2024-153376 filed on Sep. 5, 2024, No. 2024-159268 filed on Sep. 13, 2024, and No. 2025-097791 filed on Jun. 11, 2025; the entire contents of which are incorporated herein by reference.

### FIELD

The present disclosure relates to a wafer grinding apparatus and a wafer grinding method for grinding a wafer, which is held on a holding surface of a chuck table, by means of a grinding wheel.

### BACKGROUND

In a grinding apparatus for grinding a wafer having devices formed on its front surface, a chuck table having a conical holding surface, which is slightly tilted downward along its outer periphery with a center thereof as an apex, may be used. On the holding surface of this chuck table, a wafer having a protective tape adhered to its front surface is held. A method is employed in which a lower surface of an annular grinding wheel is brought into contact with a radial portion of a back surface of the wafer that rotates together with the chuck table, thereby grinding the entire back surface of the wafer (see, for example, Japanese Patent Application Laid-Open Publications Nos. 2008-264913, 2013-119123, and 2014-226749).

In such a grinding method, inclination of the chuck table is adjusted so that the radial portion of the holding surface of the chuck table becomes parallel to the lower surface of the grinding wheel, thereby grinding the wafer to achieve a uniform in-plane thickness.

### SUMMARY

However, merely adjusting the inclination between a rotation axis of the chuck table and a rotation axis of the grinding wheel is insufficient or difficult to meet recent demands for reducing the in-plane thickness variation of wafers to 0.1 μm or less.

In addition, in a grinding method in which a bonded wafer composed of a support wafer and a device wafer bonded together is held on a chuck table with the support wafer facing downward, and the back surface (upper surface) of the device wafer of the bonded wafer is ground, there may be cases where a surface of the device wafer, which is the lower surface bonded to the support wafer, may have unevenness in a ring shape on the surface due to an adhesive used to bond the device wafer and the support wafer. In such cases, the thickness of the ground device wafer may not become uniform.

The present disclosure has been made in view of the above problems, and an object thereof is to provide a wafer grinding apparatus and a wafer grinding method capable of grinding a wafer to a uniform thickness over its entire surface while suppressing in-plane thickness variation.

According to a first aspect of the present disclosure, a grinding apparatus for grinding a wafer includes a chuck table configured to hold the wafer on a holding surface thereof; a grinding unit configured to grind the wafer by rotating an annular array of grinding stones about a grinding stone rotation axis extending through a center of the annular array of grinding stones; an elevating mechanism configured to elevate and lower the chuck table and the grinding unit relative to each other; a grinding water supply device configured to supply grinding water to an area where the grinding stones contact the wafer; a spray nozzle configured to spray warm water or cold water from above the holding surface onto at least a part of the holding surface or a part of the wafer held on the holding surface; a thickness measuring device configured to measure thicknesses at a plurality of positions in the wafer held on the holding surface; and a controller configured to control spraying water from the spray nozzle toward the wafer so as to expand or contract the chuck table via the wafer and thereby changing a height of the holding surface such that: warm water is sprayed toward a position, of which thickness value among a plurality of thickness values measured at the plurality of positions by the thickness measuring device indicates a thickness greater than a preset target thickness, or a position, of which thickness value indicates a thickness greater than an average value of the plurality of thickness values; or cold water is sprayed toward a position, of which thickness value indicates a thickness less than the preset target thickness, or a position, of which thickness value indicates a thickness less than the average value of the plurality of thickness values.

According to a second aspect of the present disclosure, a wafer grinding method performed using the grinding apparatus includes a holding step including holding the wafer on the holding surface of the chuck table; and a grinding step including grinding the wafer to a preset finished thickness by rotating the chuck table about a table rotation axis extending through a center of the holding surface. The grinding step includes measuring thicknesses at the plurality of positions in a radial portion of the wafer by the thickness measuring device while grinding the wafer with the grinding stones, and spraying warm water toward the position, of which thickness value among the plurality of thickness values measured at the plurality of positions by the thickness measuring device indicates the thickness greater than the preset target thickness, or the position, of which thickness value indicates the thickness greater than the average value of the plurality of thickness values; or splaying cold water toward the position, of which thickness value indicates the thickness less than the preset target thickness, or the position, of which thickness value indicates the thickness less than the average value of the plurality of thickness values.

According to a third aspect of the present disclosure, a wafer grinding method performed using the grinding apparatus includes a holding step including holding the wafer on the holding surface of the chuck table; a preliminary grinding step including grinding the wafer to a thickness that does not reach a preset finished thickness; a thickness measurement step including measuring thicknesses at a plurality of positions in the wafer preliminarily ground in the preliminary grinding step by the thickness measuring device; a holding surface height changing step including changing the height of the holding surface by causing the chuck table to expand or contract via the preliminarily ground wafer, by spraying warm water from the spray nozzle toward a position, of which thickness value among a plurality of thickness values measured in the thickness measurement step indicates a thickness greater than the preset target thickness, or a position, of which thickness value indicates a thickness greater than an average value of the plurality of thickness values measured in the thickness measurement step, or spraying cold water from the spray nozzle toward a position, of which thickness value among the plurality of thickness values measured in the thickness measurement step indicates a thickness less than the preset target thickness, or a position, of which thickness value indicates a thickness less than the average value of the plurality of thickness values measured in the thickness measurement step; and a finish grinding step including grinding the preliminarily ground wafer to the preset finished thickness.

According to a fourth aspect of the present disclosure, a wafer grinding method performed using the grinding apparatus includes a first holding step including holding a first wafer on the holding surface of the chuck table; a first grinding step including griding the first wafer to a preset finished thickness; a thickness measurement step including measuring thicknesses at a plurality of positions in the first wafer ground in the first grinding step by the thickness measuring device; a storage step including storing a first position, of which thickness value among a plurality of thickness values measured in the thickness measurement step indicates a thickness greater than the finished thickness, and a second position, of which thickness value among the plurality of thickness values measured in the thickness measurement step indicates a thickness less than the finished thickness, in the controller; a separation step including separating the first wafer from the holding surface of the chuck table; a second holding step including holding a second wafer on the holding surface of the chuck table; a holding surface height correction step including correcting the height of the holding surface via the second wafer by spraying warm water from the spray nozzle toward the first position in the second wafer as stored in the controller or spraying cold water from the spray nozzle toward the second position in the second wafer as stored in the controller; and a second grinding step including grinding the second wafer to the finished thickness after or during the holding surface height correction step.

According to a fifth aspect of the present disclosure, the wafer may be a bonded wafer including a support wafer and a device wafer having a bonding surface on which devices are formed and which is bonded to the support wafer; in the holding step, the first holding step, or the second holding step, the chuck table may hold the support wafer thereon by suction; and the grinding step, the preliminary grinding step, the finish grinding step, the first grinding step, or the second grinding step may include grinding the device wafer.

According to a sixth aspect of the present disclosure, a grinding apparatus for grinding a wafer includes a chuck table configured to hold the wafer on a holding surface thereof; a grinding unit configured to grind the wafer by rotating an annular array of grinding stones about a grinding stone rotation axis extending through a center of the annular array of grinding stones; an elevating mechanism configured to elevate and lower the chuck table and the grinding unit relative to each other; a grinding water supply device configured to supply grinding water to an area where the grinding stones contact the wafer; a thickness measuring device configured to measure thicknesses at a plurality of positions in the wafer held on the holding surface; a spot heater configured to locally heat the wafer held on the holding surface; and a holding surface height change controller configured to control the spot heater to heat the wafer at a position, of which thickness value among a plurality of thickness values measured at the plurality of positions by the thickness measuring device indicates a thickness greater than a preset target thickness, or a position, of which thickness value indicates a thickness greater than an average value of the plurality of thickness values, thereby causing the chuck table to locally expand via the wafer and elevating the holding surface.

According to a ninth aspect of the present disclosure, a wafer grinding method using the grinding apparatus includes a holding step including holding the wafer on the holding surface; and a grinding step including grinding the wafer to a preset finished thickness by rotating the chuck table about a table rotation axis extending through a center of the holding surface. The grinding step includes measuring thicknesses at the plurality of positions in the wafer by the thickness measuring device while grinding the wafer with the grinding stones, and while measuring, heating the wafer locally by the spot heater at the position, of which thickness value among the plurality of thickness values measured at the plurality of positions by the thickness measuring device indicates the thickness greater than the preset target thickness, the preset target thickness being thicker than the preset finished thickness, or the position, of which thickness value indicates the thickness greater than the average value of the plurality of thickness values, thereby elevating the holding surface locally via the wafer.

According to a tenth aspect of the present disclosure, a wafer grinding method performed using the grinding apparatus includes a holding step including holding the wafer on the holding surface; a preliminary grinding step including grinding the wafer preliminarily to the preset target thickness which does not reach a preset finished thickness; a thickness measurement step including measuring thicknesses at a plurality of positions in the wafer preliminarily ground by the thickness measuring device; a holding surface elevation step including heating the preliminarily ground wafer locally with the spot heater at the position, of which thickness value among the plurality of thickness values measured in the thickness measurement step indicates the thickness greater than the target thickness, or the position, of which thickness value indicates the thickness greater than the average value of the plurality of thickness values, thereby causing the chuck table to locally expand via the preliminarily ground wafer and elevating the holding surface locally via the wafer; and a finish grinding step including grinding the preliminarily ground wafer to the finished thickness after or during the holding surface elevation step.

According to an eleventh aspect of the present disclosure, a wafer grinding method performed using the grinding apparatus includes a first holding step including holding a first wafer on the holding surface; a first grinding step including griding the first wafer to a preset finished thickness; a thickness measurement step including measuring thicknesses at a plurality of positions in the first wafer ground in the first grinding step by the thickness measuring device; a storage step including storing a position, of which thickness value among a plurality of thickness values measured at the plurality of positions in the thickness measurement step indicates a thickness greater than the finished thickness; a separation step including separating the first wafer from the holding surface; a second holding step including holding a second wafer on the holding surface; a holding surface elevation step including heating the second wafer locally with the spot heater at the position in the second wafer as stored in the storage step, thereby elevating the holding surface locally via the second wafer; and a second griding step including grinding the second wafer to the preset finished thickness after or during the holding surface elevation step.

According to the wafer grinding method of the second aspect of the present disclosure, while the thicknesses of the wafer being ground is measured, warm water may be sprayed from the spray nozzle toward a portion, of which measured thickness is greater than the preset target thickness, or cold water may be sprayed form the spray nozzle toward a portion, of which measured thickness is less than the target thickness. Therefore, the wafer held on the holding surface of the chuck table during the grinding step may be ground with reduced in-plane thickness variation across the surface, thereby achieving a uniform thickness over the entire wafer.

According to the wafer grinding method of the third aspect of the present disclosure, the wafer may be preliminarily ground to the thickness, which does not reach the preset finished thickness. Then, the thicknesses at a plurality of positions in the radial portion in the preliminarily ground wafer are measured, and based on the measured thickness values, warm water may be sprayed from the spray nozzle toward the portion, of which thickness value is greater than the target thickness, or cold water may be sprayed from the spray nozzle toward the portion, of which thickness value is less than the target thickness. As a result, the chuck table may be expanded or contracted via the preliminarily ground wafer, thereby changing the height of the holding surface. Consequently, the wafer may be ground with reduced in-plane thickness variation across its surface, achieving uniform thickness over the entire wafer.

According to the wafer grinding method of the fourth aspect of the present disclosure, the first wafer may be ground to the preset finished thickness, and the thicknesses of the first wafer at the plurality of positions may be measured. The controller may store the first position of the first wafer, where the measured thickness is greater than the finished thickness and the second position of the first wafer, where the measured thickness is less than the finished thickness. A portion of the holding surface of the chuck table corresponding to the first position may be heated and expanded via the second wafer, and a portion of the holding surface of the chuck table corresponding to the second position may be cooled and contracted via the second wafer. Accordingly, the height of the holding surface of the chuck table may be corrected. As a result, the second wafer held on the chuck table may be ground with reduced in-plane thickness variation, achieving a uniform finished thickness across the entire wafer surface.

According to the wafer grinding method of the fifth aspect of the present disclosure, even in the case where the wafer is a bonded wafer where two wafers are bonded, in the grinding method according to the second through fourth aspects, one of the wafers being ground among the two wafers in the bonded wafer may be ground to a uniform thickness over the entire surface with reduced in-plane thickness variation.

According to the wafer grinding method of the ninth through eleventh aspects of the present disclosure, a portion of the wafer, of which thickness value among the plurality of thickness values measured by the thickness measurement device is greater than the preset target thickness, may be heated by the spot heater, thereby causing the chuck table to expand to change the height of the holding surface. Accordingly, at the position where the thickness of the wafer is greater, the grinding stones may contact earlier than the other portions, so that the in-plane thickness variation of the wafer may be reduced, allowing the wafer to be ground to a uniform thickness across its entire surface.

### BRIEF DESCRIPTION OF THE DRAWINGS

FIG. 1 is a perspective view, partially removed, showing a wafer grinding apparatus according to a first embodiment of the present disclosure.

FIG. 2A is a cross-sectional side view of a main portion of the grinding apparatus showing a grinding step in a wafer grinding method according to a first aspect of the first embodiment, and FIG. 2B is a diagram showing a thickness distribution in a radial direction of the wafer.

FIG. 3 is a cross-sectional side view of the main portion of the grinding apparatus showing positioning of a spray nozzle and the grinding step in the wafer grinding method according to the first aspect of the first embodiment.

FIG. 4 is a flowchart illustrating a procedure in the wafer grinding method according to the first aspect of the first embodiment.

FIG. 5 is a block diagram showing steps in the wafer grinding method according to a second aspect of the first embodiment.

FIG. 6A is a cross-sectional side view of the main portion of the grinding apparatus showing a thickness measurement step in the wafer grinding method according to the second aspect of the first embodiment, and FIG. 6B is a diagram showing a thickness distribution in the radial direction of the wafer.

FIG. 7 is a cross-sectional side view of the main portion of the grinding apparatus showing a holding surface height changing step in the wafer grinding method according to the second aspect of the first embodiment.

FIG. 8 is a flowchart illustrating a procedure in the wafer grinding method according to the second aspect of the first embodiment.

FIG. 9 is a block diagram showing steps in the wafer grinding method according to a third aspect of the first embodiment.

FIG. 10A is a cross-sectional side view of the main portion of the grinding apparatus showing the thickness measurement step in the wafer grinding method according to the third aspect of the first embodiment, and FIG. 10B is a diagram showing a thickness distribution in the radial direction of the wafer.

FIG. 11 is a cross-sectional side view of the main portion of the grinding apparatus showing a holding surface height correcting step in the wafer grinding method according to the third aspect of the first embodiment.

FIG. 12 is a flowchart illustrating the procedure in the wafer grinding method according to the third aspect of the first embodiment.

FIG. 13 is a cross-sectional side view of the main portion of the grinding apparatus showing the grinding step to a bonded wafer in the first embodiment.

FIG. 14 is a schematic perspective view of a grinding apparatus according to a second embodiment.

FIG. 15 is a schematic view of the grinding apparatus according to the second embodiment, partially vertically cross-sectioned, illustrating a holding step in a first grinding method of the second embodiment.

FIG. 16 is a schematic view of the grinding apparatus according to the second embodiment, partially vertically cross-sectioned, illustrating a processing step performed during the grinding step in the first grinding method of the second embodiment.

FIG. 17 is a flow diagram showing steps in the first grinding method of the second embodiment.

FIG. 18A is an explanatory view of the thickness measurement step performed during the grinding step in the first grinding method of the second embodiment, and FIG. 18B is a diagram showing a thickness distribution in the radial direction of the wafer.

FIG. 19 is an explanatory view of a spot heater positioning step performed during the grinding step in the first grinding method of the second embodiment.

FIG. 20 is an explanatory view of a holding surface elevation step performed during the grinding step in the first grinding method of the second embodiment.

FIG. 21 is an explanatory view of the holding surface elevation step performed during the grinding step in the first grinding method of the second embodiment.

FIG. 22 is an explanatory view of an unloading step in the first grinding method of the second embodiment.

FIG. 23 is a flow diagram showing steps in a second grinding method of the second embodiment.

FIG. 24 is an explanatory view of the thickness measurement step in the second grinding method of the second embodiment.

FIG. 25 is an explanatory view of the holding surface elevation step in the second grinding method of the second embodiment.

FIG. 26 is a flow diagram showing steps in a third grinding method of the second embodiment.

FIG. 27 is an explanatory view of the thickness measurement step in the third grinding method of the second embodiment.

FIG. 28 is an explanatory view of a separation step in the third grinding method of the second embodiment.

FIG. 29 is an explanatory view of the holding surface elevation step in the third grinding method of the second embodiment.

FIG. 30 is a schematic view of the bonded wafer being ground similarly to the bonded wafer shown in FIG. 16.

FIG. 31A is a schematic view of the grinding apparatus, partially vertically cross-sectioned, according to a first modified example; FIG. 31B is a partially enlarged view of the grinding apparatus shown in FIG. 31A; and FIG. 31C is a schematic perspective view showing the nozzle of the first modified example as viewed from below.

FIG. 32 is a schematic view of part of the grinding apparatus, partially vertically cross-sectioned, according to a second modified example.

### DESCRIPTION OF EMBODIMENTS

Hereinafter, embodiments of the present disclosure will be described with reference to the accompanying drawings.

### First Embodiment

### Configuration of Grinding Apparatus

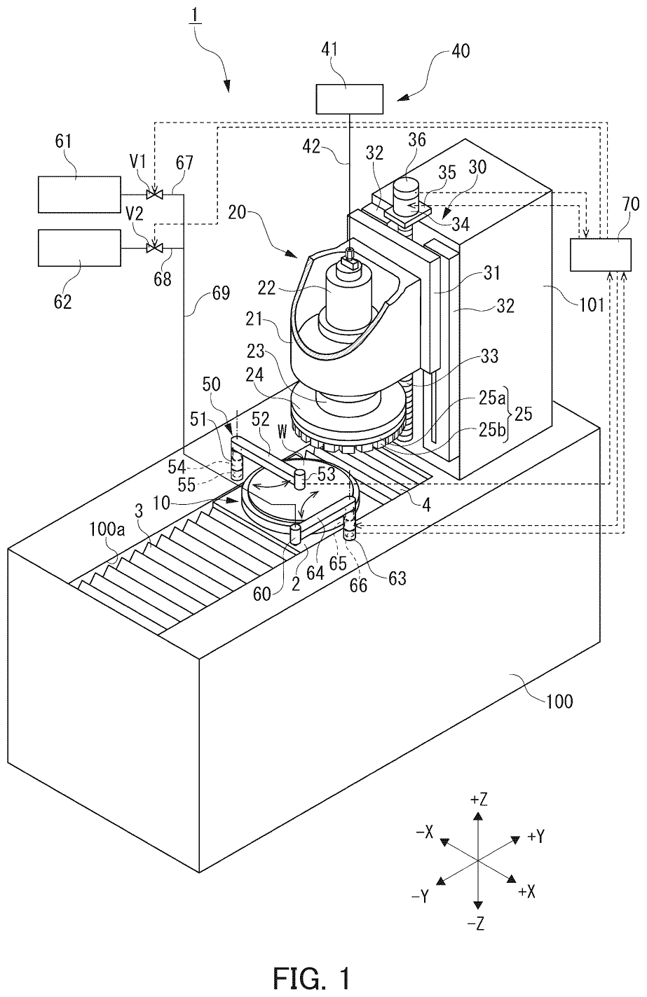

First, a configuration of a grinding apparatus according to a first embodiment of the present disclosure will be described. In the following description, the directions indicated by arrows in FIG. 1 are referred to as an X-axis direction (left-right direction), a Y-axis direction (front-rear direction), and a Z-axis direction (vertical direction, i.e., up-down direction). The X-axis, Y-axis, and Z-axis directions are orthogonal to one another. The X-axis and Y-axis directions are approximately horizontal directions. Among the double-headed arrows indicating the Z-axis direction, the +Z direction is defined as upward, and the −Z direction is defined as downward.

A grinding apparatus 1 shown in FIG. 1 is configured to grind a thin, disk-shaped wafer W, which is a workpiece and includes a first wafer, a second wafer, and a bonded wafer. The grinding apparatus 1 includes the following components.

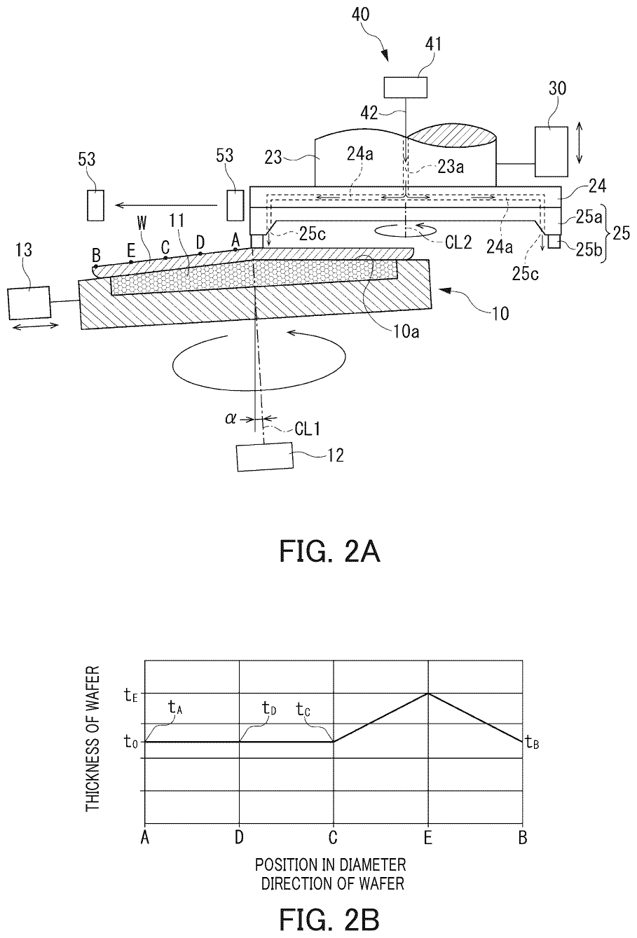

That is, the grinding apparatus 1 includes, as its main components, a chuck table 10 that holds and rotates the wafer W; a table rotation mechanism 12 (see FIG. 2) that rotationally drives the chuck table 10; a grinding unit 20 that grinds the wafer W held on the chuck table 10; and an elevating mechanism 30 that moves the grinding unit 20 up and down in the vertical direction (Z-axis direction) with respect to a holding surface 10a of the chuck table 10 (see FIG. 2). The grinding apparatus 1 further includes a grinding water supply device 40 that supplies grinding water toward the inside of an annular array of grinding stones 25b (see FIG. 2A) during grinding of the wafer W; a thickness measuring device 50 that measures the thicknesses at a plurality of radial positions of the wafer W during grinding; a spray nozzle 60 that sprays warm or cold water toward at least part of the radial portion of the holding surface 10a of the chuck table 10 or toward an upper surface of the wafer W held on the holding surface 10a; and a controller 70 that, based on the thicknesses at the plurality of radial positions measured by the thickness measuring device 50, positions the spray nozzle 60 at positions on the wafer W that are thinner or thicker relative to a preset target thickness, and sprays warm or cold water from the spray nozzle 60 toward the wafer W. The preset target thickness may be an average value or a median value of the thicknesses measured by the thickness measuring device 50.

Here, the wafer W is composed, for example, of a single-crystal silicon substrate. On a surface of the wafer W, which faces downward in the state shown in FIG. 1, a plurality of devices (not shown) are formed. These devices are protected by a not-shown protective tape that is adhered to the surface of the wafer W. The wafer W is held by suction on the holding surface 10a of the chuck table 10 via the protective tape on its front surface (the lower surface in FIG. 1), and its back surface (the upper surface in FIG. 1) is ground by the annular array of grinding stones 25b (see FIG. 2A) of the grinding unit 20 while receiving a supply of grinding water from the grinding water supply device 40.

Next, the configurations of the chuck table 10 and the table rotation mechanism 12, the grinding unit 20, the elevating mechanism 30, the grinding water supply device 40, the thickness measuring device 50, the spray nozzle 60, and the controller 70, as the main components of the grinding apparatus 1, will be described respectively.

### Chuck Table and Table Rotation Mechanism

The chuck table 10 is a disk-shaped member, and as shown in FIG. 2A, a disk-shaped porous member 11 is incorporated in its central portion. An upper surface of the porous member 11 constitutes a holding surface 10a for holding the wafer W. The porous member 11 is made of, for example, a porous ceramic and is selectively connected to a suction source (not shown), such as a vacuum pump or an ejector.

Here, as shown in FIG. 2A, the upper surface of the chuck table 10 (porous member 11) forms a conical holding surface 10a that is tilted downward from the center toward the outer periphery. The surface of the wafer W (the lower surface in FIG. 2A) is held on this holding surface 10a with a protective tape (not shown) facing downward. It should be noted that, in FIG. 2A, the inclination of the conical holding surface 10a of the chuck table 10 is exaggerated for illustrative purposes; in practice, the inclination is so slight that it is visually unrecognizable to naked eyes.

The chuck table 10 is rotationally driven, by the table rotation mechanism 12 shown in FIG. 2A, in the direction of the arrow (counterclockwise) about a table rotation axis CL1 that passes through an apex (center) of the holding surface 10a. Specifically, the chuck table 10 includes an integrally formed rotation shaft (not shown) that extends vertically downward from its center. This shaft is rotationally driven about the table rotation axis CL1 at a predetermined speed by the table rotation mechanism 12. The table rotation mechanism 12 includes a servo motor (not shown) as a drive source, and also includes components such as an encoder (not shown) that detects a rotation speed, a rotation direction, and a rotation angle of the servo motor.

As shown in FIG. 1, the grinding apparatus 1 according to the present embodiment includes a rectangular box-shaped base 100 that is elongated in the Y-axis direction (front-rear direction). A rectangular opening 100a that is elongated in the Y-axis direction is formed in the upper surface of the base 100, and the chuck table 10 is exposed through the opening 100a. The periphery of the chuck table 10 within the opening 100a is covered by a rectangular plate-shaped cover 2. Front (−Y) and rear (+Y) portions of the opening 100a with respect to the cover 2 are respectively sealed by bellows-type expandable covers 3, 4 that expand and contract as the cover 2 moves. Thus, the opening 100a remains closed regardless of the position of the chuck table 10 along the Y-axis, preventing foreign matter from entering the interior of the base 100.

The chuck table 10 is further configured such that its inclination is adjustable by an unillustrated tilt adjustment mechanism. Specifically, the table rotation axis CL1 of the chuck table 10 may be tilted by an angle α relative to the vertical line, as shown in the drawing, so that a radial portion of the holding surface 10a of the chuck table 10 may be adjusted to be parallel to the lower surfaces of the grinding stones 25b.

Furthermore, the chuck table 10 is movable in the horizontal (Y-axis) direction by a horizontal movement mechanism 13 (see FIG. 2A) housed within the base 100. Since the horizontal movement mechanism 13 is constituted by a well-known ball screw mechanism, detailed illustration and description thereof are omitted.

### Grinding Unit

As shown in FIG. 1, the grinding unit 20 includes a spindle motor 22, which serves as a rotational drive source and is housed in a holder 21; a vertical spindle 23 that is rotationally driven by the spindle motor 22; a disk-shaped mount 24 attached to a lower end of the spindle 23; and the grinding wheel 25 that is detachably mounted on a lower surface of the mount 24. The grinding wheel 25 includes a disk-shaped base 25a and the plurality of grinding stones 25b, which are annularly arranged on the lower surface of the base 25a and serve as machining tools. Each grinding stone 25b is a rectangular block-shaped tool for grinding the wafer W, and lower surfaces of grinding stones 25b form a grinding surface that comes into contact with the upper surface (i.e., the surface to be ground) of the wafer W.

The spindle 23 of the grinding unit 20 rotates about a grinding wheel rotation axis CL2 together with the mount 24 and the grinding wheel 25. In the grinding apparatus 1 of the present embodiment, however, the grinding wheel rotation axis CL2 is arranged vertically and is not tiltable. In contrast, the table rotation axis CL1 of the chuck table 10 may be tilted by the predetermined angle α relative to the vertical grinding wheel rotation axis CL2, as shown for example in FIG. 2A, by means of the unillustrated tilt adjustment mechanism. With this configuration, the holding surface 10a of the chuck table 10 may be tilted by the angle α with respect to the horizontal plane.

### Elevating Mechanism

The elevating mechanism 30 is a mechanism that moves the grinding unit 20 toward or away from the holding surface 10a of the chuck table 10. As shown in FIG. 1, the elevating mechanism 30 is disposed on a front surface facing in the Y-axis direction of a rectangular box-shaped column 101, which is vertically erected at an end (rear end) of the upper surface of the base 100 on the +Y-axis direction. The elevating mechanism 30 elevates or lowers a rectangular plate-shaped elevating plate 31, which is attached to a back surface of the holder 21 of the grinding unit 20, in the Z-axis direction along a pair of left and right guide rails 32, together with the holder 21, and the spindle 23 and the grinding wheel 25 which are held by the holder 21. Here, the pair of left and right guide rails 32 are disposed vertically and in parallel with each other on the front surface of the column 101.

A rotatable ball screw 33 is vertically installed along the Z-axis direction (up-down direction) between the pair of left and right guide rails 32. An upper end of the ball screw 33 is connected to a servo motor 34 that serves as a drive source and is capable of forward and reverse rotation. The servo motor 34 is mounted vertically on the column 101 via a rectangular plate-shaped bracket 35 attached to an upper surface of the column 101. A lower end of the ball screw 33 is rotatably supported by the column 101. A nut member (not shown), which horizontally projects rearward (in the +Y-axis direction) from a back surface of the elevating plate 31, is threaded onto the ball screw 33. An encoder 36 is provided on the servo motor 34 to detect a rotation direction and a rotational speed of the servo motor 34. A detection signal from the encoder 36 is transmitted to the controller 70, and the controller 70, upon receiving the signal, controls the drive of the servo motor 34 based on the detection signal. Optionally, a movement amount of the elevating plate 31 and the grinding unit 20 may also be obtained based on a pulse signal output from the encoder 36.

Accordingly, by activating the servo motor 34 to rotate the ball screw 33 in the forward or reverse directions, the elevating plate 31 having the unillustrated nut member threadedly engaged with the ball screw 33 is moved up or down along the pair of guide rails 32 together with the grinding unit 20. As a result, the grinding unit 20 moves vertically, and an amount to be ground (grinding allowance) by the grinding stones 25b with respect to the wafer Wis set.

### Grinding Water Supply Device

The grinding water supply device 40 supplies grinding water, such as pure water, to a grinding region, which is the contact area between the grinding stones 25b and the wafer W during grinding, and ejects the grinding water from inside the annular array of grinding stones 25b while the wheel is rotating. More specifically, as shown in FIG. 1, the grinding water supply device 40 includes a grinding water supply source 41 such as a water pump. A pipe 42 extending from the grinding water supply source 41 is connected to an unillustrated supply passage formed vertically along the axis of the spindle motor 22. The supply passage formed in the spindle motor 22 communicates with a supply passage 23a formed vertically along the axis of the spindle 23 (see FIG. 2A). The supply passage 23a communicates with a plurality of supply passages 24a that extend radially outward from the center of the mount 24. A plurality of nozzles 25c are formed in the base 25a of the grinding wheel 25, each extending vertically downward from a corresponding one of the supply passages 24a formed in the mount 24.

Accordingly, the grinding water supplied from the grinding water supply source 41 to the spindle motor 22 via the pipe 42 is sprayed toward the upper surface of the wafer W from the plurality of nozzles 25c formed in the base 25a of the grinding wheel 25, through the supply passage 23a formed in the spindle 23 as shown in FIG. 2A and the plurality of supply passages 24a formed in the mount 24.

### Thickness Measuring Device

The thickness measuring device 50 is configured to measure, in a non-contact manner, the thickness of the wafer W being ground by the grinding unit 20 at a plurality of radial positions of the wafer W. As shown in FIG. 1, the thickness measuring device 50 includes a thickness sensor 53 mounted to a distal end of an arm 52 that extends horizontally from an upper end of a support shaft 51, which vertically erects near the chuck table 10 on the base 100 and is rotatable. The thickness sensor 53 may be, for example, an optical interferometric film-thickness gauge that irradiates the wafer W with light (e.g., infrared light) having a wavelength transmissive to the wafer W and measures the wafer thickness based on interference between light reflected from the upper surface and light reflected from the lower surface of the wafer. Alternatively, the thickness measuring device 50 may measure the wafer thickness by transmitting ultrasonic vibrations toward the wafer W, receiving ultrasonic vibrations respectively reflected from its upper and lower surfaces, and calculating the thickness. The thickness measuring device 50 may instead be configured to measure, in a non-contact manner, a height of the holding surface 10a and a height of the upper surface of the wafer W using a holding-surface height measuring device and a wafer upper-surface height measuring device, and to obtain the wafer thickness from the difference between these heights. Either optical or ultrasonic techniques may be used in the thickness measuring device 50.

The support shaft 51 incorporates a motor 54, which serves as a drive source for rotating the support shaft 51, and an encoder 55, which detects a rotation angle and a rotation direction of the motor 54. The motor 54 and the encoder 55 are electrically connected to the controller 70. When a detection signal is transmitted from the encoder 55 to the controller 70, the controller 70 drives and controls the motor 54 based on the received detection signal. In other words, the controller 70 recognizes the position, in the radial direction of the wafer W, of the measurement point being measured by the thickness sensor 53, based on the detection signal from the encoder 55.

Accordingly, by actuating the motor 54 to rotate the support shaft 51 and thereby pivot the arm 52 above the holding surface 10a of the chuck table 10, the thickness sensor 53 attached to the distal end of the arm 52 is reciprocally moved in the horizontal direction along the radial direction of the wafer W, which is held on the holding surface 10a of the rotating chuck table 10 and is being ground by the grinding stones 25b. This enables the thickness at any of a plurality of positions across the radial portion of the surface of the wafer W being ground to be measured. Alternatively, instead of horizontally moving the single thickness sensor 53 as described above, the thickness measuring device 50 may be configured with a plurality of thickness sensors 53 arranged at a plurality of positions along the radial portion of the holding surface 10a.

### Spray Nozzle

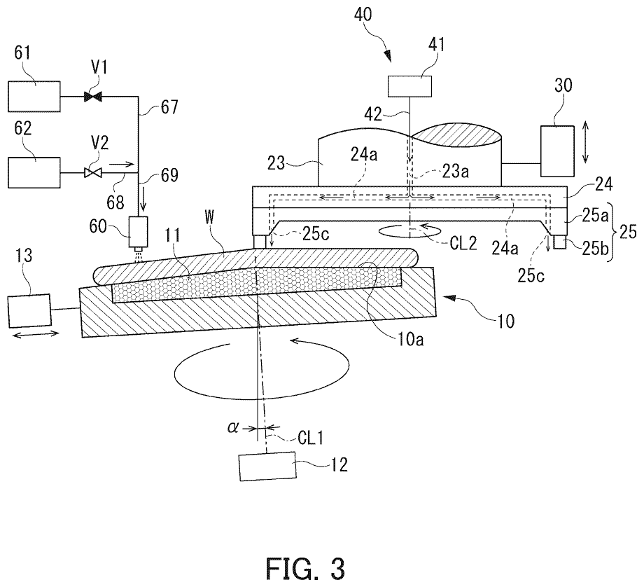

The spray nozzle 60 is configured to spray cold water or warm water (in the present embodiment, warm water) onto at least one position of the wafer W being ground (see FIG. 3), from a cold water supply source 61 or a warm water supply source 62 shown in FIG. 1. The spray nozzle 60 is mounted at a tip of an arm 64 that extends horizontally from an upper end of a support shaft 63, which vertically erects rotatably in the vicinity of the chuck table 10 on the base 100. The support shaft 63 incorporates a motor 65, which serves as a drive source for rotating the shaft, and an encoder 66 that detects a rotation angle and a rotation direction of the motor 65. The motor 65 constitutes a horizontal movement mechanism that moves (horizontally pivots) the spray nozzle 60 above the wafer W. The motor 65 and the encoder 66 are electrically connected to the controller 70. When a detection signal from the encoder 66 is transmitted to the controller 70, the controller 70 drives and controls the motor 65 based on the received detection signal.

As shown in FIG. 1, pipes 67, 68 respectively extending from the cold water supply source 61 and the warm water supply source 62 merge into a single pipe 69, and the pipe 69 is connected to the spray nozzle 60. On the pipes 67, 68, on-off valves V1, V2 are provided respectively. These on-off valves V1, V2 are electrically connected to the controller 70, and their opening and closing operations are controlled by the controller 70.

Accordingly, by activating the motor 65 that constitutes the horizontal movement mechanism to swing the arm 64 about the support shaft 63, the spray nozzle 60 attached to the distal end of the arm 64 is moved horizontally in the radial direction of the wafer W above the wafer W, thereby enabling warm or cold water to be sprayed onto any desired position in the radial portion of the wafer W (see FIG. 3). Note that, instead of moving the single spray nozzle 60 horizontally in the radial direction of the wafer W as described above, two or more spray nozzles may be moved in the same manner. Alternatively, a plurality of spray nozzles 60 may be arranged at multiple positions in the radial portion of the holding surface 10a.

### Controller

The controller 70 shown in FIG. 1 includes a CPU (Central Processing Unit) that performs arithmetic processing according to a control program, and storage components such as a ROM (Read Only Memory) and a RAM (Random Access Memory). In particular, in the present embodiment, the controller 70 functions to position the spray nozzle 60 at portions of the wafer W where the thickness (thickness value) measured by the thickness sensor 53 during grinding becomes greater or smaller than a preset target thickness, and, while rotating the chuck table 10 together with the wafer W, to spray warm or cold water from the spray nozzle 60, thereby locally expanding or contracting at least part of the holding surface 10a of the chuck table 10 via the wafer W. Details of this operation will be described later.

### Wafer Grinding Method

Next, embodiments of the wafer W grinding methods according to first to third aspects of the present disclosure, which are implemented using the grinding apparatus 1 configured as described above, will be described.

### First Aspect

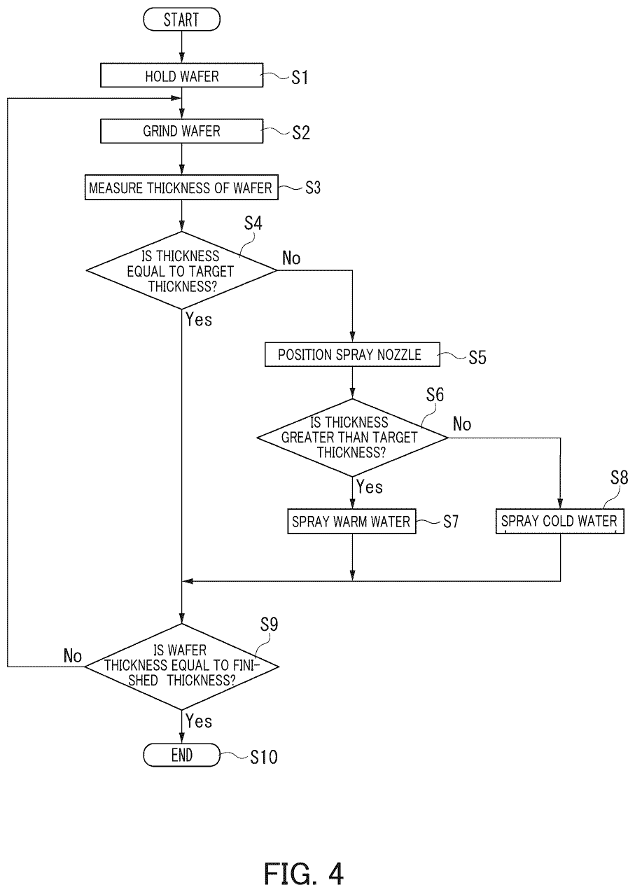

The wafer W grinding method according to the first aspect includes the following steps performed in this order to grind the wafer W:
1) Holding step; and
2) Grinding step.
   The details of each step will be described below with reference to steps S1-S10 in the flowchart shown in FIG. 4.

### 1) Holding Step

The holding step is a step of holding the wafer W on the holding surface 10a of the chuck table 10. As shown in FIG. 2A, the wafer W is placed, with the unillustrated protective tape facing downward, on the holding surface 10a of the chuck table 10, which has been tilted by the unillustrated tilt adjustment mechanism such that the table rotation axis CL1 is tilted at the angle α with respect to the vertical direction. When the porous member 11 of the chuck table 10 is connected to the unillustrated suction source in this state, the porous member 11 is evacuated by the suction source, thereby generating a negative pressure in the porous member 11. Accordingly, the wafer W is drawn and held by suction on the conical holding surface 10a of the chuck table 10 due to the negative pressure (step S1). In this case, the thin wafer W is deformed into an umbrella shape with its center as an apex, fitted to the shape of the holding surface 10a of the chuck table 10.

### 2) Grinding Step

In the grinding step, the chuck table 10, together with the wafer W held thereon, is horizontally moved in the +Y-axis direction (rightward in FIG. 3) by the horizontal movement mechanism 13, and the chuck table 10 is positioned such that an outer circumference of the annular array of grinding stones 25b of the grinding wheel 25 should pass over the center of the wafer W. The tilt angle α of the chuck table 10 is set, as shown in FIG. 3, to a value such that a radial portion (rightward half in FIG. 3) of the holding surface 10a of the chuck table 10 becomes parallel to the horizontal lower surfaces (grinding surfaces) of the grinding stones 25b.

In the above state, the chuck table 10 and the wafer W held thereon are rotationally driven at a predetermined speed in the direction indicated by the arrow (counterclockwise) around the table rotation axis CL1 by the table rotation mechanism 12. Simultaneously, the grinding wheel 25 of the grinding unit 20 shown in FIG. 1 is rotationally driven at a predetermined speed in the same direction as the rotation of the chuck table 10 (counterclockwise) around the grinding wheel rotation axis CL2 by the spindle motor 22. Then, from this state, the grinding unit 20 descends by means of the elevating mechanism 30, and when the grinding stone 25b of the grinding wheel 25 comes into contact with the radial portion of the upper surface of the wafer W, the entire surface of the wafer W is ground by the grinding stone 25b (step S2). During this process, grinding water is supplied from the grinding water supply source 41 of the grinding water supply device 40 through the pipe 42 (see FIG. 1), an unillustrated supply passage formed along the axis of the spindle motor 22, the supply passage 23a formed along the axis of the spindle 23 as shown in FIG. 2A, and the plurality of supply passages 24a formed in the mount 24, and is then sprayed from the plurality of vertically extending nozzles 25c formed in the base 25a of the grinding wheel 25 toward the upper surface of the wafer W. As a result, grinding swarf generated during grinding of the wafer W is removed by the grinding water, and frictional heat generated at the contact portion between the grinding stone 25b and the wafer W is absorbed by the grinding water, thereby cooling the contact portion.

During the above-described grinding step, while the upper (back) surface of the wafer W is being ground by the grinding stones 25b, thickness values at a plurality of positions of the radial portion of the wafer W are measured by the thickness sensor 53 of the thickness measuring device 50 (step S3). Specifically, when the support shaft 51 of the thickness measuring device 50 shown in FIG. 1 is rotated within a predetermined angular range by the motor 54, the arm 52 attached to the upper end of the support shaft 51 pivots horizontally around the support shaft 51. As a result, the thickness sensor 53 mounted at the tip of the arm 52 moves reciprocally between the central portion and the peripheral edge of the wafer W, as illustrated in FIG. 2A. In the present embodiment, thickness of the wafer W is measured by the thickness sensor 53 at five radial positions: a center point A; an outer peripheral point B; an intermediate point C between the center point A and the outer peripheral point B; a measurement point D between the center point A and the intermediate point C; and a measurement point E between the intermediate point C and the outer peripheral point B. Note that the number of measurement points on the wafer W is not limited to five.

Additionally, although in the present embodiment the thickness measuring device 50 uses an arrangement in which the thickness sensor 53 is mounted at the tip of the arm 52 that pivots horizontally about the support shaft 51, an arrangement in which five thickness sensors 53 are fixed at respective positions along the horizontal arm 52 that does not pivot horizontally may alternatively be used.

FIG. 2B shows the results of the thicknesses of the wafer W at the center point A, the measurement point D, the intermediate point C, the measurement point E, and the outer peripheral point B measured by the thickness sensor 53, as described above. In the present embodiment, the thickness t_{E} at the measurement point E of the wafer W is the greatest, while the thicknesses t_{A}, t_{D}, t_{C}, and t_{B} measured at the center point A, the measurement point D, the intermediate point C, and the outer peripheral point B, respectively, are all equal to a same value (preset target thickness t₀ described later).

Then, as described above, after the thicknesses t_{A}, t_{D}, t_{C}, t_{E}, and t_{B} at the center point A, the measurement point D, the intermediate point C, the measurement point E, and the outer peripheral point B of the wafer W are measured, and before warm or cold water is sprayed from the spray nozzle 60 as described later, the controller 70 determines whether these thicknesses match the preset target thickness t₀ (step S4), which is set in advance (see FIG. 2B)

In the present embodiment, as shown in FIG. 2B, each of the thicknesses t_{A}, t_{D}, t_{C}, and t_{B} at the center point A, the measurement point D, the intermediate point C, and the outer peripheral point B of the wafer W, excluding the measurement point E, is equal to the target thickness t₀. However, since the thickness t_{E} measured at the measurement point E is greater than the target thickness t₀ (t_{E}>t₀), the determination result in step S4 is No, and the spray nozzle 60 is positioned accordingly (step S5).

Specifically, by activating the motor 65 shown in FIG. 1 to rotate the support shaft 63 by a predetermined angle, the arm 64 attached to the upper end of the support shaft 63 horizontally pivots, causing the spray nozzle 60 attached to the tip of the arm 64 to move horizontally above the wafer W. As shown in FIG. 3, the spray nozzle 60 is thereby positioned straight above the circumference passing through the measurement point E of the wafer W. That is, in this positioning of the spray nozzle 60, as shown in FIG. 3, the spray nozzle 60 is positioned straight above the measurement point E of the wafer W, where the thickness t_{E} exceeds the target thickness t₀.

As described above, when the spray nozzle 60 is positioned straight above the circumference passing through the measurement point E of the wafer W (step S5), the controller 70 shown in FIG. 1 determines whether the thickness t_{E} at the measurement point E of the wafer W exceeds the target thickness t₀ (step S6).

If, as in the present embodiment, the result of the above determination shows that the thickness t_{E} at the measurement point E of the wafer W exceeds the target thickness t₀ (t_{E}>t₀) (step S6: Yes in FIG. 4), then, as shown in FIG. 3, while the chuck table 10 is rotated at a predetermined speed in the direction of the arrow by the table rotation mechanism 12, warm water is sprayed from the spray nozzle 60 toward the measurement point E of the wafer W, and a ring-shaped portion of the holding surface 10a corresponding to the measurement point E is heated by the warm water through the wafer W (step S7). Specifically, as shown in FIG. 3, the controller 70 opens the on-off valve V2 and closes the on-off valve V1. Then, warm water is supplied from the warm water supply source 62 through the pipes 68, 69 to the spray nozzle 60. The warm water is sprayed from the spray nozzle 60 toward the measurement point E of the wafer W, so that the ring-shaped portion passing through the measurement point E of the wafer W is heated by the warm water, thereby thermally expanding this portion.

Here, the thickness t_{E} at the measurement point E of the wafer W is greater than the thicknesses t_{A}, t_{D}, t_{C}, and t_{B} at the other points, which are the center point A, the measurement point D, the intermediate point C, and the outer peripheral point B, respectively, and also exceeds the target thickness t₀. When the portion of the holding surface 10a corresponding to the measurement point E of the wafer W is heated by warm water through the wafer W, the area straight below the measurement point E on the holding surface 10a expands in a ring-like shape. Consequently, the portion of the wafer W at measurement point E is ground to become thinner than it was before the warm water was sprayed, resulting in a thickness equal to that at the other measurement points, namely t_{A}, t_{D}, t_{C}, and t_{B} .

Conversely, when the measured thickness t_{E} at the measurement point E of the wafer W is smaller than the target thickness t₀ (that is, t_{E}<t₀) as in the case where the result of step S6 is No, the controller 70 closes the on-off valve V2 and opens the on-off valve V1. As a result, cold water is supplied from the cold water supply source 61 through the pipes 67, 69 to the spray nozzle 60, and the cold water is sprayed from the spray nozzle 60 toward the measurement point E of the wafer W. Consequently, the portion of the holding surface 10a corresponding to the measurement point E of the wafer W is cooled in a ring-like pattern (step S8 in FIG. 4). Then, the area straight below the measurement point E on the holding surface 10a contracts in a ring-like manner. Accordingly, a portion of the wafer W corresponding to the measurement point E becomes thicker than before the cold water was sprayed, and is ground such that the thickness thereof is equal to those at the other measurement points, namely t_{A}, t_{D}, t_{C}, and t_{B}. When there are multiple measurement points on the wafer W at which the thickness exceeds the target thickness t₀, the positioning of the spray nozzle 60 and the spraying of warm or cold water from the spray nozzle 60 are repeated for each of those measurement points.

Then, when warm water is sprayed from the spray nozzle 60 toward the wafer W (step S7), or when cold water is sprayed from the spray nozzle 60 toward the wafer W (step S8), the controller 70 determines whether the thickness of the wafer W, as measured by the thickness measuring device 50, has reached a predetermined finished thickness. If the wafer W has been ground to the finished thickness (step S9: Yes), a series of the grinding processes for the wafer W is completed (step S10).

On the other hand, if the wafer W has not been ground to the predetermined finished thickness (step S9: No), the processes from step S2 to step S9 are repeated until the thickness of the wafer W reaches the finished thickness.

As described above, in the grinding method for grinding the wafer W according to the first aspect, the thickness of the wafer W is measured during grinding, and warm water is sprayed from the spray nozzle 60 onto portions of the wafer W that are thicker than the predetermined target thickness, or cold water is sprayed onto portions that are thinner than the target thickness. As a result, the wafer W held on the holding surface 10a of the chuck table 10 during the grinding process may be ground such that the in-plane thickness variation is maintained low and the wafer W has a uniform thickness across its entire surface.

In the above embodiment, whether warm or cold water is to be sprayed is determined depending on whether the measured thickness of the wafer W matches the target thickness. Optionally, a permissible range (target range) may be defined for the target thickness, and warm or cold water may be sprayed when the measured thickness deviates from this target range. The target thickness may also be set as an average value (e.g., moving average), a median value (e.g., moving median), or a mode of the thicknesses measured by the thickness measuring device 50.

### Second Aspect

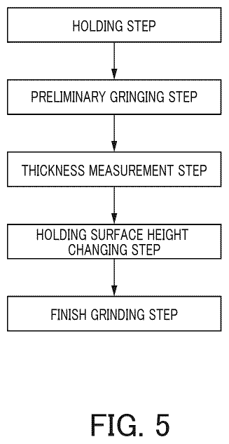

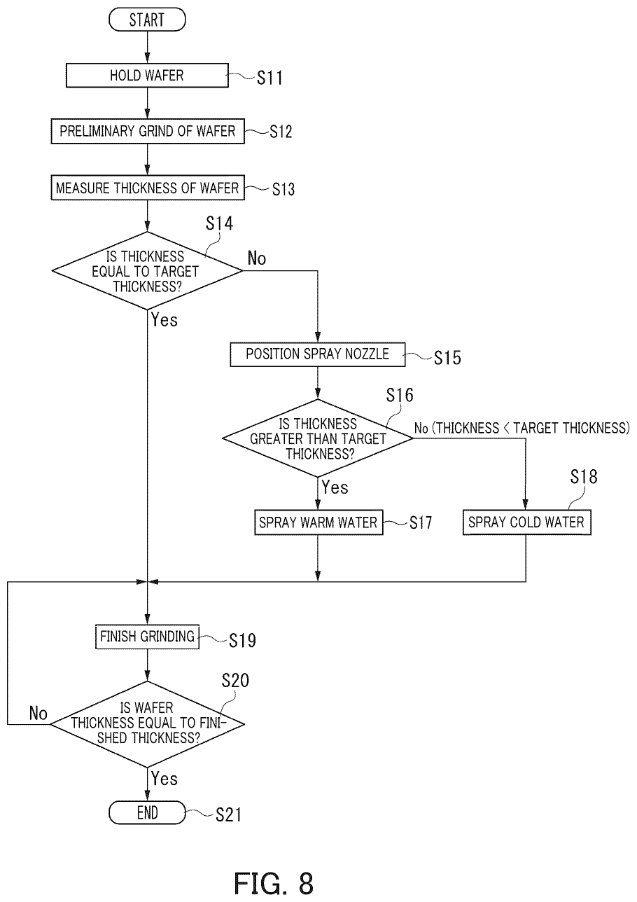

Next, a wafer W grinding method according to the second aspect, which is implemented using the grinding apparatus 1 shown in FIG. 1, will be described with reference to FIGS. 5-8. As shown in FIG. 5, this grinding method includes the following steps executed in this order:
1) Holding step;
2) Preliminary grinding step;
3) Thickness measurement step;
4) Holding surface height changing step; and
5) Finishing grinding step.
   Details of each step will be described below with reference to steps S11-S21 in the flowchart of FIG. 8.

### 1) Holding Step

The holding step is a step in which the wafer W is held on the holding surface 10a of the chuck table 10 (step S11). Since this holding step is the same as the holding step in the first aspect described above, illustration and detailed explanation thereof are omitted.

### 2) Preliminary Grinding Step

The preliminary grinding step is a step of grinding the wafer W partway, in which the wafer W is ground to a preset thickness that does not reach the finished thickness (i.e., a preset target thickness that is thicker than the finished thickness) (step S12).

In the preliminary grinding step, the chuck table 10 is positioned such that the outer circumference of the annular array of grinding stones 25b of the grinding wheel 25 should pass over the center of the wafer W. In this state, the chuck table 10 and the wafer W held thereon are rotationally driven at a predetermined speed in the direction of the arrow (counterclockwise) about the table rotation axis CL1 by the table rotation mechanism 12, and the grinding wheel 25 of the grinding unit 20 shown in FIG. 1 is also rotationally driven at a predetermined speed around the grinding wheel rotation axis CL2 in the same direction as the rotation of the chuck table 10 (counterclockwise). From this state, the grinding unit 20 is lowered by the elevating mechanism 30, and when the grinding stones 25b of the grinding wheel 25 come into contact with a radial portion of the upper surface of the wafer W, the wafer W is ground by the grinding stones 25b to the target thickness that does not reach the finished thickness (preliminary grinding).

### 3) Thickness Measurement Step

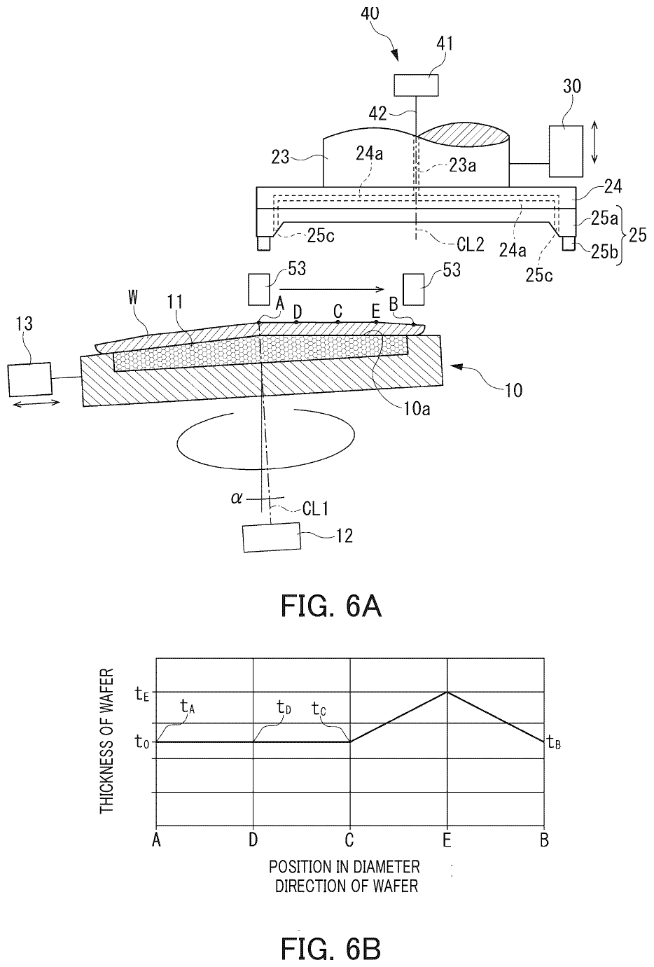

The thickness measurement step is a step of measuring the thickness of the wafer W that has been preliminarily ground in the preceding preliminary grinding step. In this step, the thicknesses at a plurality of positions in the radial portion of the wafer W are measured by the thickness sensor 53 of the thickness measuring device 50 (step S13). Specifically, as shown in FIG. 6A, the thickness sensor 53 moves above the wafer W from the center toward the outer periphery. In the present embodiment, thickness of the wafer W is measured by the thickness sensor 53 at five positions along the radial direction: the center point A; the outer peripheral point B; the intermediate point C between the center point A and the outer peripheral point B; the measurement point D between the center point A and the intermediate point C; and the measurement point E between the intermediate point C and the outer peripheral point B. Note that the number of measurement points on the wafer W is not limited to five.

FIG. 6B shows the results of the thicknesses of the wafer W at the center point A, the measurement point D, the intermediate point C, the measurement point E, and the outer peripheral point B measured by the thickness sensor 53, as described above. In the present embodiment, the thickness t_{E} at the measurement point E is the greatest, while the thicknesses t_{A}, t_{D}, t_{C}, and t_{B} measured at the center point A, the measurement point D, the intermediate point C, and the outer peripheral point B, respectively, are all equal to the same value (preset target thickness t₀).

### 4) Holding Surface Height Changing Step:

When the thicknesses t_{A}, t_{D}, t_{C}, and t_{B} at the center point A, the measurement point D, the intermediate point C, and the outer peripheral point B of the wafer W are measured as described above, the controller 70 determines whether these measured thicknesses match a preset target thickness t₀ (see FIG. 6B), which has been set in advance prior to the spraying of warm or cold water from the spray nozzle 60, as described later (Step S14).

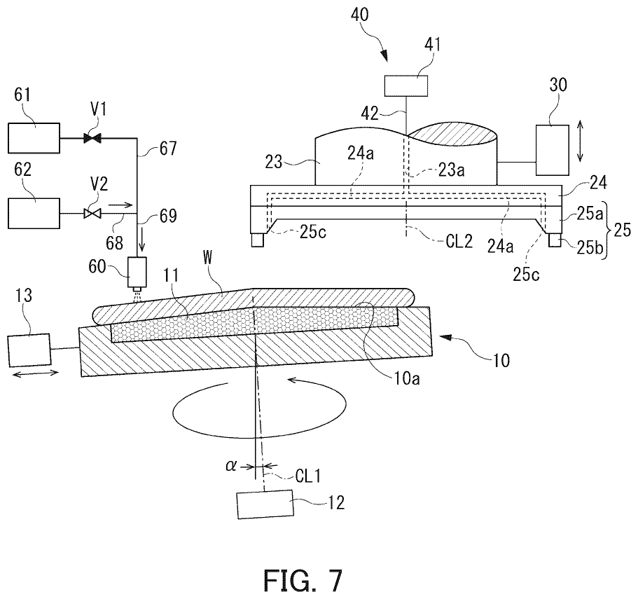

In this embodiment, as shown in FIG. 6B, since the thickness t_{E} at the measurement point E of the wafer W does not match the target thickness (Step S14: No), the spray nozzle 60 is positioned accordingly (Step S15). That is, in this nozzle positioning step, as shown in FIG. 7, the spray nozzle 60 is positioned straight above the measurement point E of the wafer W, where the thickness t_{E} exceeds the target thickness t₀ (Step S15).

Specifically, by activating the motor 65 shown in FIG. 1 to rotate the support shaft 63 by a predetermined angle, the arm 64 attached to the upper end of the support shaft 63 pivots horizontally. As a result, the spray nozzle 60 attached to the tip of the arm 64 moves horizontally above the wafer W and, as shown in FIG. 7, is positioned straight above the circumference passing through the measurement point E of the wafer W.

As described above, when the spray nozzle 60 is positioned straight above the circumference passing through the measurement point E of the wafer W, the controller 70 shown in FIG. 1 determines whether the thickness t_{E} at the measurement point E of the wafer W exceeds the target thickness t₀ (step S16).

If, as in the present embodiment, the result of the above determination shows that the thickness t_{E} at the measurement point E of the wafer W exceeds the target thickness t₀ (t_{E}>t₀) (step S16: Yes), then, as shown in FIG. 7, while the chuck table 10 is rotated at a predetermined speed in the direction of the arrow by the table rotation mechanism 12, warm water is sprayed from the spray nozzle 60 toward the measurement point E of the wafer W, and a ring-shaped portion of the holding surface 10a corresponding to the measurement point E is heated by the warm water through the wafer W (step S17). Specifically, as shown in FIG. 7, the controller 70 opens the on-off valve V2 and closes the on-off valve V1. Then, warm water is supplied from the warm water supply source 62 through the pipes 68, 69 to the spray nozzle 60. The warm water is sprayed from the spray nozzle 60 toward the measurement point E of the wafer W, so that the ring-shaped portion passing through the measurement point E of the wafer W is heated by the warm water and thermally expands, and the height of the holding surface 10a is thereby increased.

Here, the thickness t_{E} at the measurement point E of the wafer W is greater than the thicknesses t_{A}, t_{D}, t_{C}, and t_{B} at the other points, which are the center point A, the measurement point D, the intermediate point C, and the outer peripheral point B, respectively, and also exceeds the target thickness t₀. When the portion of the holding surface 10a corresponding to the measurement point E of the wafer W is heated by warm water through the wafer W, the area straight below the measurement point E on the holding surface 10a expands in a ring-like shape. Consequently, the portion of the wafer W at measurement point E is ground to become thinner than it was before the warm water was sprayed, resulting in a thickness equal to that at the other measurement points, namely t_{A}, t_{D}, t_{C}, and t_{B}

Conversely, when the measured thickness t at the measurement point E of the wafer W is smaller than the target thickness t₀ (that is, t_{E}<t₀) (step S16: No), the controller 70 closes the on-off valve V2 and opens the on-off valve V1. As a result, cold water is supplied from the cold water supply source 61 through the pipes 67, 69 to the spray nozzle 60, and the cold water is sprayed from the spray nozzle 60 toward the measurement point E of the wafer W (step S18). Consequently, the portion of the holding surface 10a straight below the measurement point E of the wafer W is cooled in a ring-like pattern and contracts, causing the height of the holding surface 10a to decrease. When there are multiple measurement points where the wafer thicknesses t_{A}, t_{D}, t_{C}, t_{E}, and t_{B} measured by the thickness measuring device 50 do not match the target thickness t₀, the positioning of the spray nozzle 60 and the spraying of either warm water or cold water from the spray nozzle 60 are repeated for the number of those measurement points.

### 5) Finishing Grinding Step

The finish grinding step is a step in which, when the thickness of the preliminarily ground wafer W does not match the target thickness t₀, the wafer W, which is held by suction on the holding surface 10a of the chuck table 10 whose height has been modified (corrected) in the preceding holding surface height changing step, is ground for finishing until its thickness reaches a predetermined finished thickness.

In the finish grinding process, the chuck table 10 is positioned such that the outer circumference of the annular array of grinding stones 25b of the grinding wheel 25 should pass over the center of the wafer W. Meanwhile, the table rotation axis CL1 is tilted by the angle α with respect to the vertical grinding wheel rotation axis CL2 so that a radial portion of the holding surface 10a of the chuck table 10 becomes parallel to the horizontal lower surfaces (grinding surfaces) of the grinding stones 25b.

In the above state, the chuck table 10 and the wafer W held thereon are rotationally driven at a predetermined speed in the direction indicated by the arrow (counterclockwise) around the table rotation axis CL1 by the table rotation mechanism 12. Simultaneously, the grinding wheel 25 of the grinding unit 20 shown in FIG. 1 is rotationally driven at a predetermined speed in the same direction as the rotation of the chuck table 10 (counterclockwise) around the grinding wheel rotation axis CL2 by the spindle motor 22. Then, from this state, the grinding unit 20 descends by means of the elevating mechanism 30, and when the grinding stone 25b of the grinding wheel 25 comes into contact with the radial portion of the upper surface of the wafer W, the entire surface of the wafer W is ground by the grinding stone 25b (step S19).

As described above, when the wafer W is ground for finishing (step S19), the controller 70 determines whether the wafer W has been ground to the finished thickness. If the thickness of the wafer W has reached the finished thickness (step S20: Yes), a series of the grinding processes for the wafer W is completed (step S21).

On the other hand, if the wafer W has not been ground to the predetermined finished thickness (step S20: No), the finish-grinding of the wafer W is repeated until the wafer W reaches the finished thickness.

As described above, in the grinding method for grinding the wafer W according to the second aspect, the wafer W is preliminarily ground to the preset thickness that does not reach the finished thickness. Then, the thicknesses at a plurality of positions of the radial portion of the preliminarily ground wafer W are measured. In a position where the measured thickness is greater than the target thickness, warm water is sprayed from the spray nozzle 60. In a position where the thickness is less than the target thickness, cold water is sprayed from the spray nozzle 60. As such, the chuck table 10 is caused to expand or contract through the preliminarily ground wafer W, thereby changing the height of the holding surface 10a. As a result, the temperature of the holding surface 10a of the chuck table 10 becomes uniform across the entire surface, and the entire holding surface 10a becomes a uniform and flat surface without unevenness or undulations. Accordingly, during the subsequent finish grinding, the wafer W may be ground such that the in-plane thickness variation is maintained low and the wafer W has a uniform thickness across its entire surface.

### Third Aspect

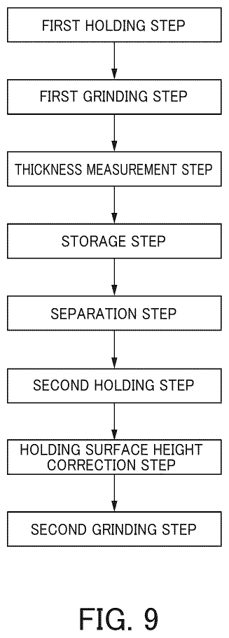

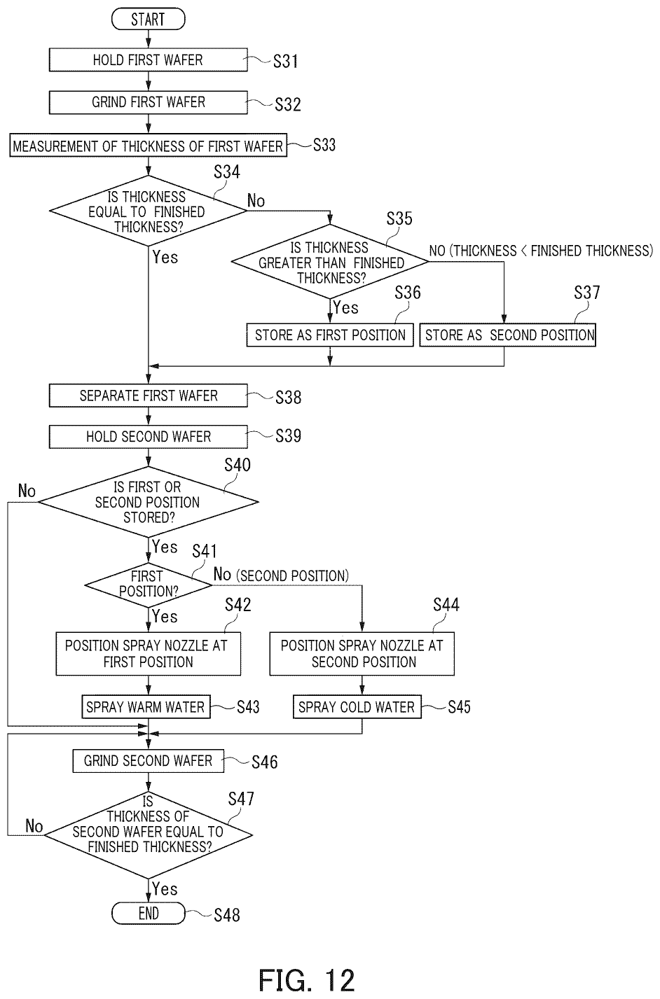

Next, a wafer W grinding method according to the third aspect, which is implemented using the grinding apparatus 1 shown in FIG. 1, will be described with reference to FIGS. 9-12. As shown in FIG. 9, this grinding method includes the following steps executed in this order:
1) First holding step;
2) First grinding step;
3) Thickness measurement step;
4) Storage step;
5) Separation step;
6) Second holding step;
7) Holding surface height correction step; and
8) Second grinding step.
   Details of each step will be described below with reference to steps S31-S48 in the flowchart of FIG. 12.

### 1) First Holding Step

The first holding step is a step of holding a first wafer W1 on the holding surface 10a of the chuck table 10 (step S31). In this holding step, the first wafer W1 is placed on the holding surface 10a of the chuck table 10 with an unillustrated protective tape facing downward. When the porous member 11 of the chuck table 10 is connected to the unillustrated suction source in this state, the porous member 11 is evacuated by the suction source, thereby generating a negative pressure in the porous member 11. Accordingly, the first wafer W1 is drawn and held by suction on the conical holding surface 10a of the chuck table 10 due to the negative pressure.

### 2) First Grinding Step

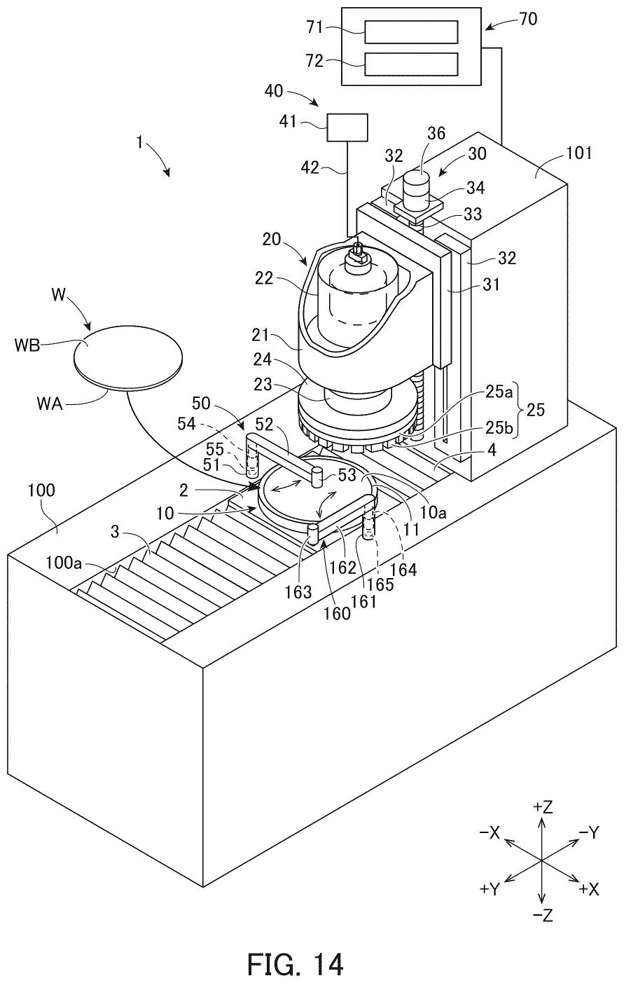

The first grinding step is a step of grinding the first wafer W1, which is held by suction on the holding surface 10a of the chuck table 10 in the preceding first holding step, to a preset finished thickness. In this first grinding step, the chuck table 10 is positioned such that the outer circumference of the annular array of grinding stones 25b of the grinding wheel 25 should pass over the center of the first wafer W1. The tilt angle α of the chuck table 10 is set to a value such that a radial portion (rightward half in FIG. 14) of the holding surface 10a of the chuck table 10 becomes parallel to the horizontal lower surface (grinding surface) of the grinding wheel 25.

In the above state, the chuck table 10 and the first wafer W held thereon are rotationally driven at a predetermined speed in the direction indicated by the arrow (counterclockwise) around the table rotation axis CL1 by the table rotation mechanism 12. Simultaneously, the grinding wheel 25 of the grinding unit 20 shown in FIG. 1 is rotationally driven at a predetermined speed in the same direction as the rotation of the chuck table 10 (counterclockwise) around the grinding wheel rotation axis CL2 by the spindle motor 22. Then, from this state, the grinding unit 20 descends by means of the elevating mechanism 30, and when the grinding stone 25b of the grinding wheel 25 comes into contact with the radial portion of the upper surface of the first wafer W1, the entire surface of the first wafer W1 is ground firstly by the grinding stones 25b (step S32).

### 3) Thickness Measurement Step

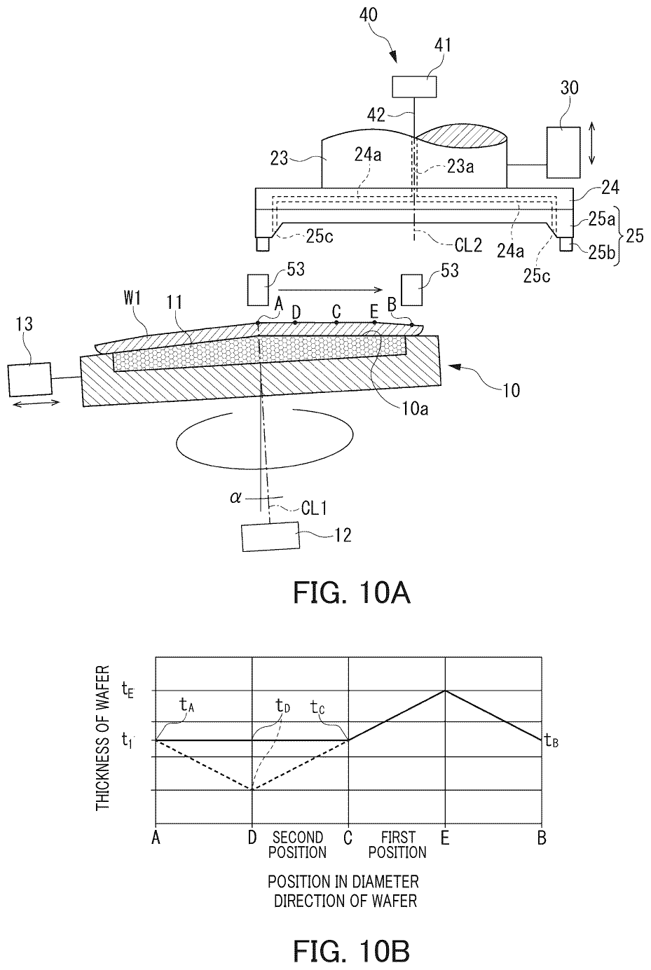

The thickness measurement step is a step of measuring the thickness of the first wafer W1 that has been ground to the finished thickness in the preceding first grinding step. In this step, the thicknesses at a plurality of positions in the radial portion of the first wafer W1 are measured by the thickness sensor 53 of the thickness measuring device 50 (step S33). Specifically, as shown in FIG. 10A, the thickness sensor 53 moves above the first wafer W1 from the center toward the outer periphery. In the present embodiment, thickness of the first wafer W1 is measured by the thickness sensor 53 at five positions along the radial direction: the center point A; the outer peripheral point B; the intermediate point C between the center point A and the outer peripheral point B; the measurement point D between the center point A and the intermediate point C; and the measurement point E between the intermediate point C and the outer peripheral point B. Note that the number of measurement points on the first wafer W1 is not limited to five.

FIG. 10B shows the results of the thicknesses of the first wafer W1 at the center point A, the measurement point D, the intermediate point C, the measurement point E, and the outer peripheral point B measured by the thickness sensor 53, as described above. In the present embodiment, the thickness t_{E} at the measurement point E is the greatest, while the thicknesses t_{A}, t_{D}, t_{C}, and t_{B} measured at the center point A, the measurement point D, the intermediate point C, and the outer peripheral point B, respectively, are all equal to the same value (finished thickness).

### 4) Storage Step

In the storage step, the controller 70 determines whether the thicknesses t_{A}, t_{B}, t_{C}, t_{D}, and t_{E}, which are measured at the center point A, the outer peripheral point B, the intermediate point C, the measurement point D, and the measurement point E of the first wafer W1, respectively, match the finished thickness t₁ (step S34). In the present embodiment, the thicknesses t_{A}, t_{D}, t_{C}, and t_{B} measured at the center point A, the measurement point D, the intermediate point C, and the outer peripheral point B, respectively, match the finished thickness t₁. However, the thickness t_{E} measured at the measurement point E does not match the finished thickness t₁ (see FIG. 10B), and therefore the judgment result at step S34 is No. Consequently, it is determined whether the thickness t_{E} is greater than the finished thickness t₁ (step S35).

In the present embodiment, since the thickness t_{E} measured at the measurement point E is greater than the finished thickness t₁ (t_{E}>t₁), this measurement point E is stored as a first position in a storage of the controller 70 (step S36). In contrast, for example, if the thickness t_{D} of the first wafer W1 measured at the measurement point D is smaller than the finished thickness t₁ (t_{D}<t₁), as indicated by the dashed line in FIG. 10B, the measurement point D is stored as a second position in the storage of the controller 70 (step S37).

On the other hand, if the thicknesses t_{A}, t_{B}, t_{C}, t_{D}, and t_{E} of the first wafer W1 measured at the center point A, the outer peripheral point B, the intermediate point C, the measurement point D, and the measurement point E, respectively, all match the finished thickness t₁ (step S34: Yes), the subsequent separation step described later is performed (step S38).

### 5) Separation Step

The separation step is a step of separating the first wafer W1 from the holding surface 10a of the chuck table 10 after the thicknesses t_{A}, t_{B}, t_{C}, t_{D}, and t_{E} at the plurality of positions in the radial portion of the first wafer W1 (namely, the center point A, the outer peripheral point B, the intermediate point C, the measurement point D, and the measurement point E) have been measured in the thickness measurement step.

In the separation step, after the grinding wheel 25 and other components are elevated by the elevating mechanism 30 and retracted above the chuck table 10, the porous member 11 of the chuck table 10 and the unillustrated suction source are disconnected, thereby releasing the first wafer W1 from the suction force generated by negative pressure. Then, in this state, the first wafer W1 is separated and removed upward from the holding surface 10a of the chuck table 10 (step S38). As a result, the holding surface 10a (the upper surface of the porous member 11) is exposed on the upper surface of the chuck table 10.

### 6) Second Holding Step

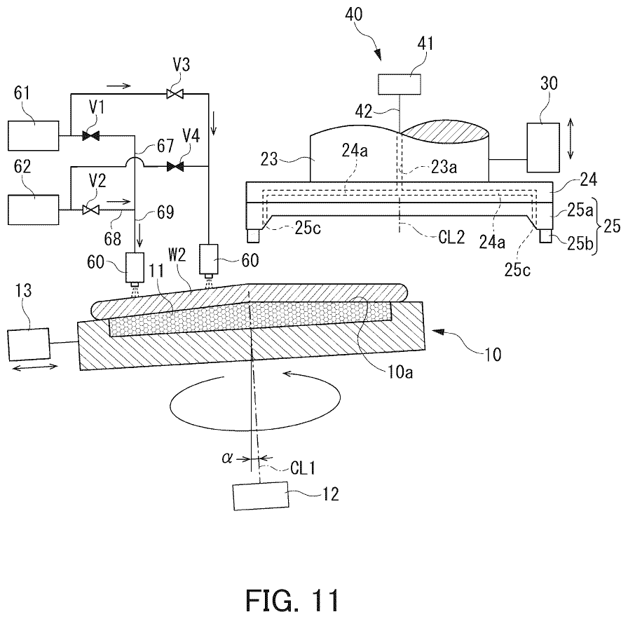

The second holding step is a step of holding a second wafer W2 on the holding surface 10a of the chuck table 10, from which the first wafer W1 was removed in the previous separation step (step S39). In this second holding step, as shown in FIG. 11, the second wafer W2 is placed on the holding surface 10a of the chuck table 10 with an unillustrated protective tape facing downward. When the porous member 11 of the chuck table 10 is connected to the unillustrated suction source, the porous member 11 is evacuated by the suction source, thereby generating a negative pressure in the porous member 11. Accordingly, the second wafer W2 is drawn and held by suction on the conical holding surface 10a of the chuck table 10 due to the negative pressure.

### 7) Holding Surface Height Correction Step

The holding surface height correction step is a step of correcting the height of the holding surface 10a of the chuck table 10. In this step, it is determined whether the storage of the controller 70 stores the first position (where the thickness of the first wafer W1 is greater than the target finish thickness t₁) or the second position (where the thickness of the first wafer W1 is less than the finished thickness t₁) (step S40).

If the storage of the controller 70 stores either the first position or the second position (step S40: Yes), it is then determined whether the stored position is the first position (step S41). If the storage stores the first position (step S41: Yes), the spray nozzle 60 is positioned above the first position, which corresponds to the measurement point E, as shown in FIG. 11 (step S42), and while the chuck table 10 and the second wafer W2 held thereon are rotated around the table rotation axis CL1 in the direction of the arrow by the table rotation mechanism 12, warm water is sprayed from the spray nozzle 60 onto the position corresponding to the measurement point E of the second wafer W2 (step S43).

For spraying warm water from the spray nozzle 60 onto the second wafer W2, as shown in FIG. 11, the on-off valve V1 remains closed, while the on-off valve V2 is opened. As a result, warm water is supplied from the warm water supply source 62 to the spray nozzle 60 via the pipes 68, 69, and is sprayed toward the position corresponding to the measurement point E of the rotating second wafer W2. As such, warm water is sprayed from the spray nozzle 60 toward the measurement point E of the second wafer W2, thereby heating the holding surface 10a via the second wafer W2. As a result, the portion of the holding surface 10a located at the position corresponding to the measurement point E thermally expands in a ring-like manner.

The portion of the holding surface 10a of the chuck table 10 corresponding to the measurement point E, at which the measured thickness t_{E} of the first wafer W1 is greater than the finished thickness t₁, has a lower temperature than the other portions. Therefore, by heating this portion with warm water, the height of the holding surface 10a is corrected. As a result, the holding surface 10a becomes a flat plane without unevenness.

On the other hand, as indicated by the broken line in FIG. 10B, when the thickness t_{D} at the measurement point D is smaller than the finished thickness t₁, and when this measurement point D is stored as the second position in the storage of the controller 70 (step S41: No), the spray nozzle 60 is positioned above the position corresponding to the measurement point D of the second wafer W2 (step S44), and cold water is sprayed from the spray nozzle 60 toward the portion corresponding to the measurement point D of the second wafer W2 (step S45). Specifically, as shown in FIG. 11, for spraying cold water onto the second wafer W2, an on-off valve V4 remains closed while an on-off valve V3 is opened. As a result, cold water is supplied from the cold water supply source 61 to the spray nozzle 60 through the path indicated by arrows and is sprayed from the spray nozzle 60 toward the portion of the rotating second wafer W2 corresponding to the measurement point D. Consequently, the portion of the holding surface 10a of the chuck table 10 corresponding to the measurement point D is cooled through the second wafer W2. In this case, the portion of the holding surface 10a corresponding to the measurement point D, where the thickness of the first wafer W1 is smaller than the finished thickness t₁, has a higher temperature than the other portions and is therefore thermally expanded. Therefore, cooling this portion with cold water causes contraction in this portion. As a result, the height of the holding surface 10a is corrected, and the surface becomes a flat plane without unevenness. Although in the above description the height of the holding surface 10a is changed by spraying warm or cold water onto the second wafer W2, it is also possible to first spray warm or cold water directly onto the holding surface 10a to change its height and then place the second wafer W2 thereon for grinding.

It should be noted that, in the present embodiment, the case where only one position, i.e., the measurement point E, on the first wafer W1 has a thickness greater than the finished thickness is described as an example. However, when the first wafer W1 has multiple such positions, warm water is sprayed by the spray nozzle 60 onto multiple corresponding positions in the second wafer W2. Furthermore, in cases where both positions thicker and thinner than the finished thickness t₁ coexist in the first wafer W1, warm water and cold water are respectively sprayed from the spray nozzle 60 onto the corresponding positions on the second wafer W2.

### 8) Second Grinding Step

The second grinding step is a step of grinding (secondly grinding) the second wafer W2, which is held by suction on the holding surface 10a of the chuck table 10 whose height has been corrected in the preceding holding surface height correction step, to the finished thickness (step S46). In this second grinding step, the chuck table 10 is positioned such that the outer circumference of the annular array of grinding stones 25b of the grinding wheel 25 should pass over the center of the second wafer W2. Meanwhile, the chuck table 10 is tilted by the illustrated angle α with respect to the vertical grinding wheel rotation axis CL2, such that a radial portion of the holding surface 10a of the chuck table 10 becomes parallel to the horizontal lower surface (grinding surface) of the grinding stones 25b.

In the above state, the chuck table 10 and the second wafer W2 held thereon are rotationally driven at a predetermined speed in the direction indicated by the arrow (counterclockwise) around the table rotation axis CL1 by the table rotation mechanism 12. Simultaneously, the grinding wheel 25 of the grinding unit 20 shown in FIG. 1 is rotationally driven at a predetermined speed in the same direction as the rotation of the chuck table 10 (counterclockwise) around the grinding wheel rotation axis CL2 by the spindle motor 22. Then, from this state, the grinding unit 20 descends by means of the elevating mechanism 30, and when the grinding stone 25b of the grinding wheel 25 comes into contact with the radial portion of the upper surface of the second wafer W2, the entire surface of the second wafer W2 is ground for finishing by the grinding stones 25b.

As described above, when the second wafer W2 is ground for finishing (step S46), the controller 70 determines whether the second wafer W2 has been ground to the finished thickness t₁. If the thickness of the second wafer W2 has reached the finished thickness t₁ (step S47: Yes), a series of the grinding processes for the second wafer W2 is completed (step S48).

On the other hand, if the second wafer W2 has not been ground to the preset finished thickness t₁ (step S47: No), the grinding of the second wafer W2 is repeated until it reaches the finished thickness t₁.

It should be noted that, in the present embodiment, the second grinding step is performed after the holding surface height correction step. However, the second grinding step may be performed simultaneously with the holding surface height correction step.

As described above, in the grinding method for grinding the second wafer W2 according to the third aspect, the first wafer W1 is ground to the preset finished thickness t₁, and the thickness of the ground first wafer W1 is measured. The controller 70 stores, as a first position, a point where the thickness exceeds the finished thickness t₁, and as a second position, a point where the thickness is less than the finished thickness t₁. Then, warm water is sprayed from the nozzle 60 onto the first position to heat and expand the corresponding portion of the holding surface 10a of the chuck table 10 through the second wafer W2, and cold water is sprayed from the nozzle 60 onto the second position to cool and contract the corresponding portion of the holding surface 10a of the chuck table 10 through the second wafer W2. As a result, the height of the holding surface 10a of the chuck table 10 is corrected, and the holding surface 10a becomes a flat surface without unevenness. Consequently, the second wafer W2 held on the holding surface 10a of the chuck table 10 may be ground such that the in-plane thickness variation is maintained low and the second wafer W2 has a uniform thickness across its entire surface.

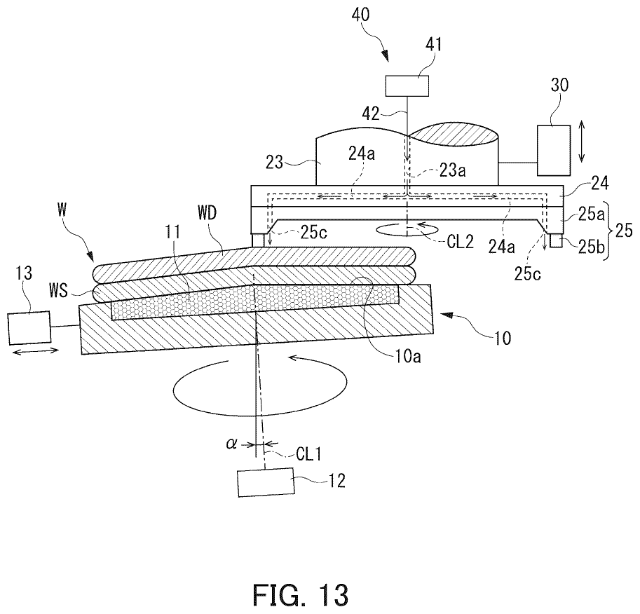

Note that the grinding methods according to the first through third aspects described above may also be similarly applied to grinding of a bonded wafer W as shown in FIG. 13. Here, the bonded wafer W is composed of a support wafer WS and a device wafer WD bonded to the support wafer WS. On a bonding surface (the lower surface in FIG. 13) of the device wafer WD to be bonded to the support wafer WS, a plurality of unillustrated devices are formed.

Then, as shown in FIG. 13, the bonded wafer W is held by suction on the holding surface 10a of the chuck table 10 with the support wafer WS facing downward, and the back surface (upper surface) of the device wafer WD is ground by the grinding wheel 25, which is rotating. In other words, when grinding the device wafer WD of the bonded wafer W, the thickness of the device wafer WD is measured by the thickness measuring device 50, and, as in the first aspect, warm or cold water is sprayed from the nozzle 60 onto the holding surface 10a to correct the height of the holding surface 10a while grinding the device wafer WD to a predetermined finished thickness. Alternatively, as in the second aspect, after the thickness of the preliminarily ground device wafer WD is measured by the thickness measuring device 50, warm or cold water is sprayed from the nozzle 60 onto the holding surface 10a to correct its height, and then the device wafer WD is ground to the predetermined finished thickness.

Further, as in the third aspect, after the device wafer WD of the bonded wafer Wis ground to the finished thickness and the thickness of the device wafer WD is measured by the thickness measuring device 50, warm or cold water is sprayed from the nozzle 60 onto the holding surface 10a to correct the height of the holding surface 10a, and then the device wafer WD of the next (and onward) bonded wafer W is ground to the predetermined finished thickness.

### Second Embodiment

Next, another embodiment of the present disclosure will be described with reference to FIGS. 14 through 29. FIG. 14 is a schematic perspective view of a grinding apparatus according to the second embodiment. In the following description, components that are the same as or equivalent to those in the first embodiment may be denoted by the same reference numerals, and explanations may be omitted or simplified. In the second embodiment, instead of the configuration in which warm or cold water is sprayed from the nozzle 60 as in the first embodiment, a heating unit 160 is provided. As shown in FIG. 14, the heating unit 160 is installed on the base 100 at a position where the chuck table 10 passes.

The heating unit 160 includes a support shaft 161 that vertically erects near the chuck table 10 on the base 100 and is rotatable, an arm 162 that extends horizontally from an upper end of the support shaft 161, and a spot heater 163 mounted at a distal end of the arm 162. The support shaft 161 internally accommodates a motor 164, which serves as a drive source for rotating the support shaft 161, and an encoder 165 that detects a rotation angle and a rotation direction of the motor 164.

The spot heater 163 may be, for example, a heater unit that combines a concave reflective mirror and a near-infrared lamp such as a halogen heater lamp, thereby enhancing directivity of an emitted high-temperature beam (heat ray). The spot heater 163 is configured to locally heat the wafer W held on the holding surface 10a by irradiating the lower wafer W with the high-temperature beam, and to change the height of the holding surface 10a by causing thermal expansion of the porous member 11 of the chuck table 10 via the wafer W.

In the heating unit 160, the motor 164 is driven to swing the arm 162 above the wafer W about the support shaft 161. As a result, the spot heater 163 attached to the tip of the arm 162 moves in the radial direction of the wafer W. This movement allows the spot heater 163 to locally heat and thereby expand the porous member 11 (holding surface 10a) of the chuck table 10 via the wafer W at a desired position within the radial region of the wafer W.

A front surface WA of the wafer W, which is to be ground by the grinding apparatus 1, may be protected by attaching an unillustrated protective tape thereto in the state shown in FIG. 14. In the grinding process, the front surface WA of the wafer W serves as the surface to be held, which is held by suction on the holding surface 10a of the chuck table 10, while a back surface WB of the wafer W (the upper surface in FIG. 14) serves as the surface to be ground.

When grinding the wafer W held on the chuck table 10, the chuck table 10 and the wafer W are moved via the horizontal movement mechanism 13 to a position below the grinding unit 20. In this state, the grinding wheel 25 of the grinding unit 20 is rotated and lowered at a predetermined rate, whereby the back surface WB of the wafer W is ground by the grinding stones 25b. For grinding the back surface WB, the chuck table 10 is rotated, for example, in the same direction as the grinding wheel 25 so that the wafer W rotates on its own axis. An outer diameter of a grinding periphery of the grinding stones 25b is larger than the radius of the holding surface 10a and passes over the center of the wafer W, thereby allowing the entire surface of the wafer W to be uniformly ground by the grinding stones 25b.

The operations of the respective components of the grinding apparatus 1 are controlled by the controller 70 (see FIG. 14). The controller 70 includes a processor that executes various processes, and a storage (memory) 71 that stores various parameters, programs, and the like. The storage 71 of the controller 70 stores, as part of the control program, for example, programs for controlling the operations of the elevating mechanism 30, the grinding unit 20, the grinding water supply device 40, the thickness measuring device 50, the heating unit 160, and so on. The controller 70 also includes a holding surface height change controller 72. In the following descriptions of the operations of each component of the grinding apparatus 1, unless the controlling entity is explicitly stated, the operation is assumed to be controlled by a control signal sent from the controller 70.

### Wafer Grinding Method

Next, first through third grinding methods of the wafer W, which are performed using the grinding apparatus 1 configured as described above in the second embodiment, will be explained.

### First Grinding Method

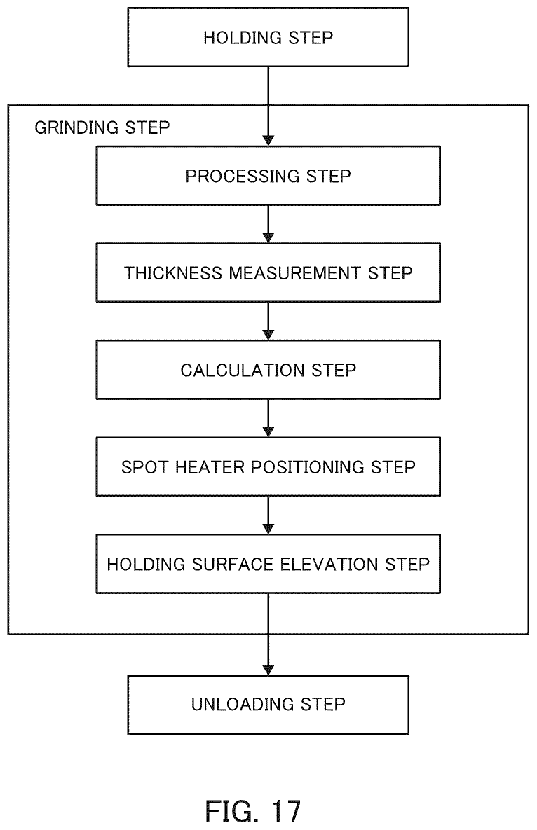

A first grinding method for grinding the wafer W according to the second embodiment will now be described. FIG. 17 is a flowchart illustrating the steps of the first grinding method. As shown in FIG. 17, the first grinding method for grinding the wafer W according to the present embodiment is a method for grinding the wafer W through the steps: 1) a holding step; 2) a grinding step; and 3) an unloading step. Each of these steps will be described in detail below.

### 1) Holding Step

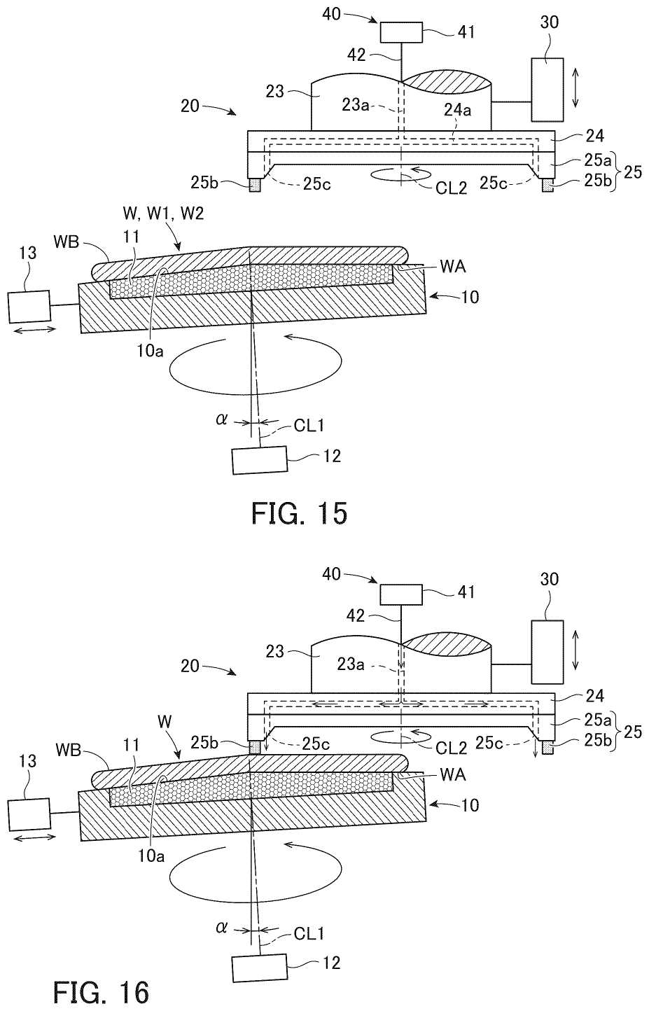

FIG. 15 is a diagram illustrating the holding step of the first grinding method. In the holding step, first, as shown in FIG. 15, the chuck table 10 is tilted by the unillustrated tilt adjustment mechanism so that its table rotation axis CL1 is tilted at the predetermined angle α with respect to the Z-axis direction. In this state, for example, the wafer W is placed on the holding surface 10a of the chuck table 10 by an unillustrated conveyer device, and the porous member 11 of the chuck table 10 is connected to the unillustrated suction source. As a result, a negative pressure is generated in the porous member 11 by evacuating with the suction source, and the wafer W is drawn and held by suction on the holding surface 10a due to the negative pressure. At this time, the wafer W is deformed into an umbrella shape with its center as an apex, fitted to the shape of the holding surface 10a.

### 2) Grinding Step

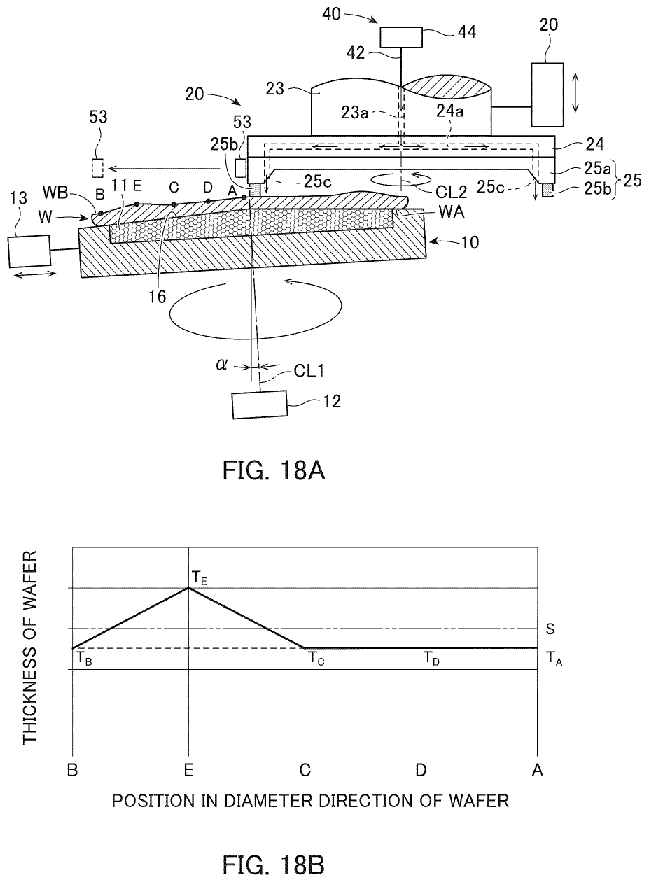

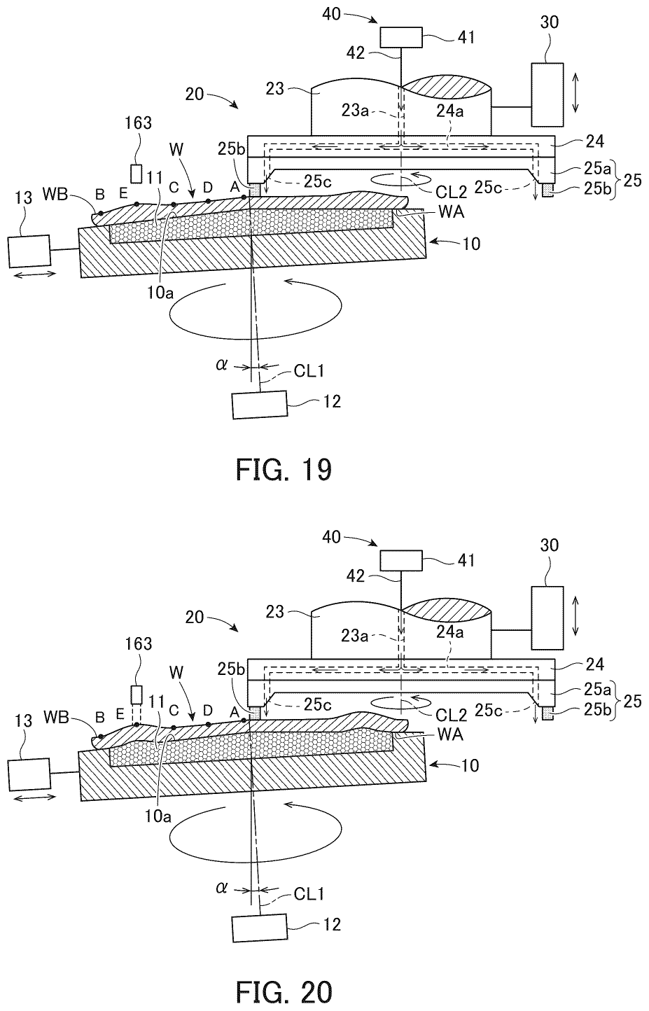

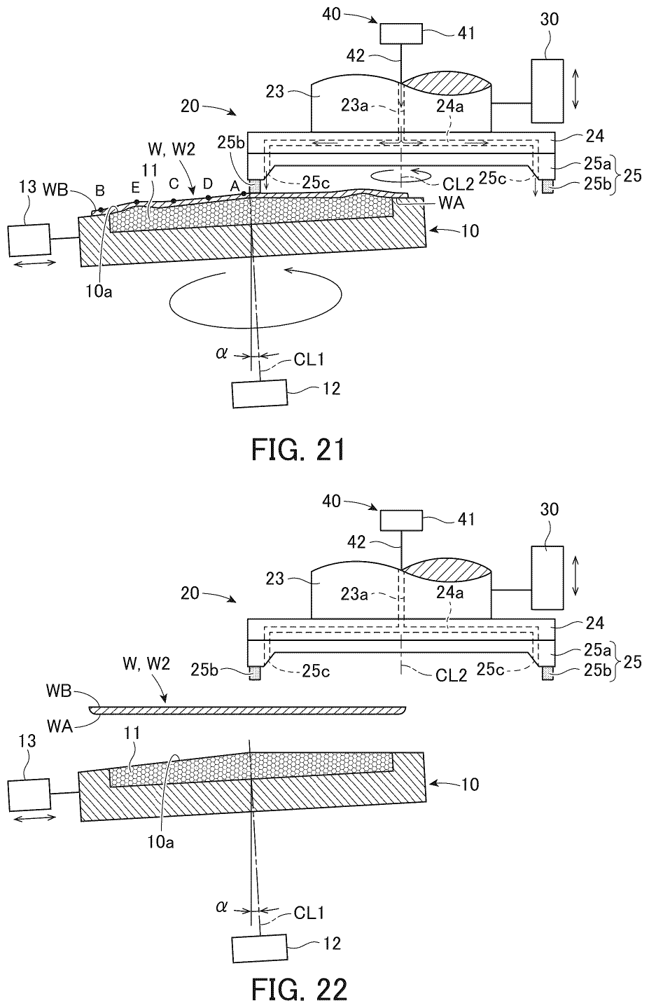

After the holding step is performed, as shown in FIG. 17, the grinding step is performed. In the grinding step of the first grinding method, the following sub-steps are performed: 2-1) a processing step; 2-2) a thickness measurement step; 2-3) a calculation step; 2-4) a spot heater positioning step; and 2-5) a holding surface elevation step. These sub-steps in the grinding step will be described below. FIG. 16 is a diagram illustrating the processing step performed in the grinding step of the first grinding method. FIG. 18A is a diagram illustrating the thickness measurement step performed in the grinding step of the first grinding method. FIG. 18B is a diagram showing a thickness distribution of the wafer in the radial direction. FIG. 19 is a diagram illustrating the spot heater positioning step performed in the grinding step of the first grinding method. FIGS. 20 and 21 are diagrams illustrating the holding surface elevation step performed in the grinding step of the first grinding method. In the first grinding method, the thickness measurement step, the calculation step, the spot heater positioning step, and the holding surface elevation step are performed in parallel with the processing step in which the back surface WB of the wafer W is ground.

### 2-1) Processing Step

In the processing step, the chuck table 10 and the wafer W held on the chuck table 10 are horizontally moved in the Y-axis direction by the horizontal movement mechanism 13, and the chuck table 10 is positioned such that the outer circumference of the annular array of grinding stones 25b should pass over the center of the wafer W. The tilt angle α of the chuck table 10 is set to a value such that a radial portion (rightward half in FIG. 15) of the holding surface 10a becomes parallel to the horizontal lower surface (grinding surface) of the annular array of grinding stones 25b.

Furthermore, the chuck table 10 and the wafer W held on the chuck table 10 are rotationally driven at a predetermined speed in the direction indicated by the arrow around the table rotation axis CL1 by the table rotation mechanism 12. Moreover, the grinding wheel 25 is rotationally driven at a predetermined speed in the same direction as the rotation direction of the chuck table 10 around the grinding wheel rotation axis CL2 by the spindle motor 22 of the grinding unit 20 (see FIG. 14).

Then, from this state, when the grinding unit 20 is lowered by the elevating mechanism 30, the grinding stones 25b come into contact with the radial portion of the back surface WB of the wafer W, as shown in FIG. 16. As a result, the entire back surface WB of the wafer W is ground by the grinding stones 25b.

During this process, grinding water is supplied from the grinding water supply source 41 of the grinding water supply device 40 through the pipe 42 and is sprayed toward the back surface WB of the wafer W from the plurality of nozzles 25c formed in the grinding wheel 25. As a result, grinding swarf generated during grinding of the wafer W is removed by the grinding water, and frictional heat generated at the contact portion between the grinding stones 25b and the wafer W is absorbed by the grinding water, thereby cooling the contact portion.

If, for example, only the above-described processing step is performed in the grinding step, the back surface WB of the wafer W is ground, and due to deformation or the like of the chuck table 10 itself caused by processing heat generated during grinding, the wafer W may not attain a uniform thickness, resulting in a thickness variation. Therefore, in the grinding step, the following steps are performed.

### 2-2) Thickness Measurement Step

While the wafer W is continuously ground in the processing step, the thickness measurement step is performed. In the thickness measurement step, the thicknesses at multiple positions in the radial portion of the wafer W being ground in the processing step are measured.

In the thickness measurement step, the support shaft 51 of the thickness measuring device 50 shown in FIG. 14 is rotated forward and backward within a predetermined angular range by the motor 54, thereby causing the arm 52, which is attached to the upper end of the support shaft 51, to horizontally swing back and forth about the shaft 51. As a result, as shown in FIG. 18A, the thickness sensor 53 located at the tip of the arm 52 pivots in reciprocation over the wafer W from the center point A toward the outer peripheral point B and back from the outer peripheral point B toward the center point A. In the first grinding method, the thickness of the wafer W is measured by the thickness sensor 53 at five points: the center point A of the wafer W, the outer peripheral point B, the intermediate point C between the center point A and the outer peripheral point B, the measurement point D between the center point A and the intermediate point C, and the measurement point E between the intermediate point C and the outer peripheral point B. The measurement by the thickness sensor 53 is performed optically and without contact with the wafer W. It should be noted that the number of measurement points is not limited to five.

FIG. 18B illustrates an example of the measurement results obtained by the thickness sensor 53, showing the thicknesses at the center point A, the measurement point D, the intermediate point C, the measurement point E, and the outer peripheral point B of the wafer W as thickness values T_{A}, T_{D}, T_{C}, T_{E}, and T_{B}, respectively. In FIG. 18B, the thickness value T_{E} at the measurement point E of the wafer W is greater than those at the other measurement points. The thickness values T_{A}, T_{D}, T_{C}, T_{E}, and T_{B}, measured by the thickness sensor 53 are output to the controller 70.

### 2-3) Calculation Step

While grinding the wafer W with the grinding stones 25b in the processing step and measurement of the thickness of the wafer W by the thickness measuring device 50 in the thickness measurement step are continued, the calculation step is performed. In the calculation step, the thickness values T_{A}, T_{D}, T_{C}, T_{E}, and T_{B} at the plurality of measurement points measured by the thickness sensor 53 of the thickness measuring device 50 in the thickness measurement step are input to the holding surface height change controller 72 of the controller 70. A target thickness S to be used for comparison with the thickness values T_{A}, T_{D}, T_{C}, T_{E}, and T_{B} at the plurality of measurement points is set in advance in the holding surface height change controller 72. The target thickness S may be, for example, determined and set by the holding surface height change controller 72 as an average value or a median value of the thickness values T_{A}, T_{D}, T_{C}, T_{E}, and T_{B} at the plurality of measurement points, or may be stored and set in the storage 71 as processing information of the wafer W prior to grinding the wafer W. Furthermore, the target thickness S may be greater than a preset finished thickness, which is a thickness after completion of the wafer W grinding, and may be set as a numerical range having an upper limit and a lower limit.

In the calculation step, the holding surface height change controller 72 compares the preset target thickness S with the thickness values T_{A}, T_{D}, T_{C}, T_{E}, and T_{B} at the plurality of measurement points. Then, among the plurality of measured thickness values T_{A}, T_{D}, T_{C}, T_{E}, and T_{B}, the portion(s) thicker than the target thickness S are identified. For example, as shown in FIG. 18B, when the target thickness S is defined as the average value (moving average) or the median value (moving median) of the thickness values T_{A}, T_{D}, T_{C}, T_{E}, and T_{B}, the thickness value T_{E} is thicker than the target thickness S. Accordingly, the position corresponding to thickness value T_{E}, where the thickness is greater than the target thickness S, is identified as the measurement point E.

### 2-4) Spot Heater Positioning Step

While continuing the processing step and the thickness measurement step and after the calculation step, the spot heater positioning step is performed. In the spot heater positioning step, the spot heater 163 of the heating unit 160 is positioned straight above the measurement point E of the wafer W, which was determined in the calculation step, via the holding surface height change controller 72. This positioning causes the support shaft 161 of the heating unit 160 to rotate by a predetermined angle through the drive of the motor 164 shown in FIG. 14. As a result, the spot heater 163 is horizontally moved above the wafer W by the arm 162 pivoting horizontally, and as shown in FIG. 19, the spot heater 163 is positioned straight above the measurement point E of the wafer W.

### 2-5) Holding Surface Elevation Step

While the processing step and the thickness measurement step continue, and after the spot heater positioning step, the holding surface elevation step is performed. In the holding surface elevation step, as shown in FIG. 20, a high-temperature beam is emitted from the spot heater 163, which has been positioned straight above the measurement point E of the wafer W in the spot heater positioning step, onto the measurement point E of the wafer W held on the holding surface 10a. At this time, grinding of the wafer W by the grinding stones 25b is continued, and rotation of both the chuck table 10 and the wafer W held thereon also continues. As a result, the high-temperature beam from the spot heater 163 heats a ring-shaped region on the wafer W concentric with the wafer W and passing through the measurement point E. This heating causes the porous member 11 of the chuck table 10 to be locally heated in a ring-shaped manner directly beneath the ring-shaped region of the wafer W, via the wafer W. As a result, the heated portion of the porous member 11, and thus of the chuck table 10, thermally expands locally in a ring shape. Consequently, the holding surface 10a of the chuck table 10 is locally elevated upward in a ring shape, resulting in an increased height in that portion. By locally elevating the ring-shaped region of the holding surface 10a that passes through the measurement point E, the corresponding ring-shaped region of the wafer W is also locally elevated upward and deformed in a bulging shape.

Then, as described above, while the thickness measurement by the thickness sensor 53, emission of a high-temperature beam from the spot heater 163, and height change of the holding surface 10a are being performed, the back surface WB of the wafer W, which is rotated by the chuck table 10, is ground by the rotating grinding stones 25b. If the height of the holding surface 10a were not changed as described above, the ring-shaped region passing through the measurement point E of the wafer W would have a larger thickness value T_{E}, resulting in a smaller grinding amount than in other regions. Consequently, a thickness variation would occur, preventing the wafer W from having a uniform thickness. In contrast, as described above, due to the expansion of the chuck table 10, the holding surface 10a rises in the ring shape. This causes the lower surfaces of the grinding stones 25b to contact the region passing through the measurement point E of the wafer W earlier than the other regions, enabling the region to be ground longer. As a result, the grinding amount across the entire surface of the wafer W may be equalized, and as shown in FIG. 21, the in-plane thickness variation of the wafer W may be reduced, allowing the wafer W to be ground to a uniform thickness across its entire surface.

As described above, as grinding of the wafer W proceeds and the thickness of the wafer W is reduced to the finished thickness, the grinding unit 20 is elevated by driving the elevating mechanism 30 based on the outputs of the thickness values T_{A}, T_{D}, T_{C}, T_{E}, and T_{B} measured by the thickness sensor 53. As a result, grinding of the single wafer W by the grinding process is completed.

### 3) Unloading Step

FIG. 22 is an explanatory diagram of the unloading step implemented in the grinding step of the first grinding method. After the grinding step is completed, the unloading step is performed. In the unloading step, rotations of the chuck table 10 and the grinding wheel 25 are stopped, and the chuck table 10 is horizontally moved in the Y-axis direction by the horizontal movement mechanism 13. Subsequently, as shown in FIG. 22, the wafer W is unloaded from the chuck table 10 via the unillustrated conveyer device, and the first grinding method with the single wafer W is completed. If grinding of a next wafer W is to be performed, the first grinding method starting from the holding step described above is repeatedly executed.

According to the first grinding method described above, the in-plane thickness variation of the wafer W may be suppressed, and the wafer W may be ground to a uniform thickness over its entire surface. This allows the wafer W to be ground with high accuracy and uniform thickness, beyond the limitations of conventional grinding based solely on adjusting the tilt angle α of the chuck table 10.

Moreover, in the first grinding method, the thickness measurement step, the calculation step, the spot heater positioning step, and the holding surface elevation step are performed concurrently with the grinding step in which the back surface WB of the wafer W is ground. Accordingly, the amount of grinding may be corrected in real time during grinding of the wafer W so as to adjust the amount of grinding of the portion where the thickness value of the wafer W is, if not corrected, large.

Next, other grinding methods according to the present embodiment will be described. In the following description, explanations of steps that are the same as or equivalent to those described in the previously explained grinding method(s) may be omitted or simplified.

### Second Grinding Method

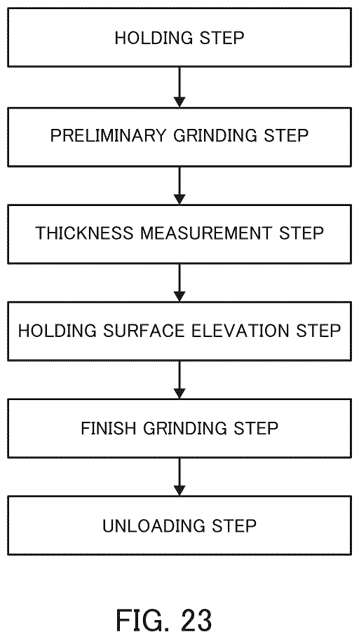

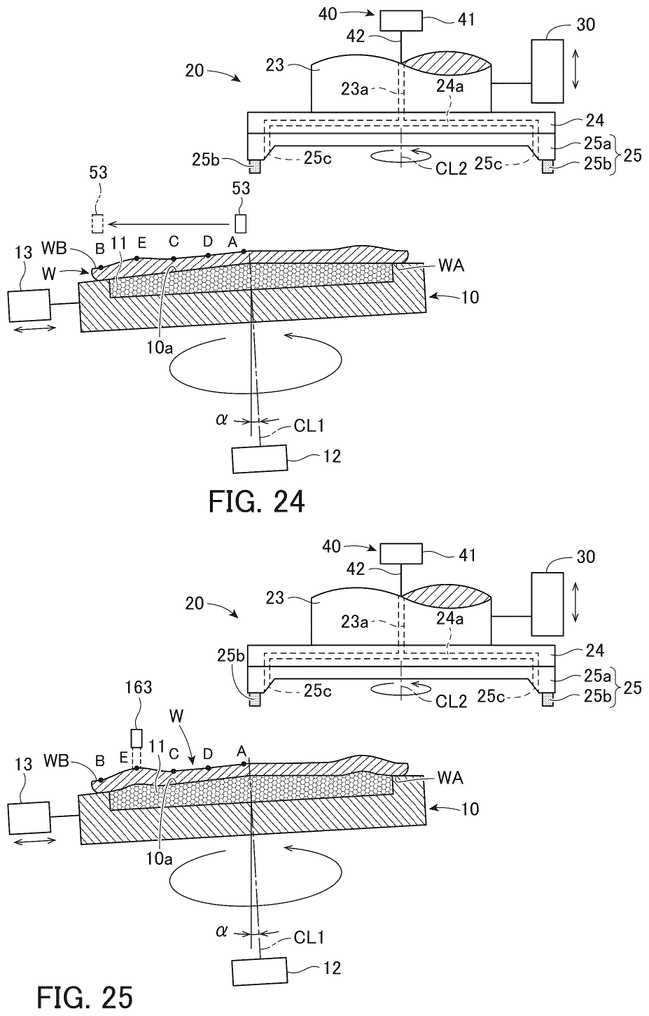

A second method for grinding the wafer W according to the second embodiment will be described below. FIG. 23 is a flow diagram showing steps in the second grinding method of the second embodiment. As shown in FIG. 23, the second grinding method according to the present embodiment is a method for grinding the wafer W through the following steps: 1) a holding step; 2) a preliminary grinding step; 3) a thickness measurement step; 4) a holding surface elevation step; 5) a finish grinding step; and 6) an unloading step. These steps will be described below. FIG. 24 is an explanatory view of the thickness measurement step in the second grinding method of the second embodiment. FIG. 25 is an explanatory diagram of the holding surface elevation step in the second grinding method.

### 1) Holding Step

The holding step of the second grinding method is performed in the same manner as the holding step of the first grinding method so that the wafer W is held on the holding surface 10a (see FIG. 15).

### 2) Preliminary Grinding Step

After the holding step is performed in the second grinding method, the preliminary grinding step is performed. This step is performed in the same manner as the processing step of the first grinding method, except that the amount to grind the wafer W differs. In the preliminary grinding step, the wafer W is ground to a predetermined thickness that does not reach the preset finished thickness (for example, a preset target thickness S). Then, as shown in FIG. 24, the grinding unit 20 is elevated by driving of the lifting mechanism 30, and the grinding process is temporarily suspended.

### 3) Thickness Measurement Step

In the second grinding method, after the preliminary grinding step is performed, the thickness measurement step is performed. This step is performed in the same manner as the thickness measurement step of the first grinding method, except that this thickness measurement step is performed while the grinding of the wafer W is temporarily suspended. In this thickness measurement step, thickness of the preliminarily ground wafer W is measured at a plurality of positions (for example, the five points described above) by the thickness sensor 53 of the thickness measuring device 50 (see FIG. 24).

### 4) Holding Surface Elevation Step

In the second grinding method, after the thickness measurement step is performed, the holding surface elevation step is performed. This step is performed in the same manner as the calculation step, the spot heater positioning step, and the holding surface elevation step of the first grinding method, except that grinding of the wafer W is temporarily suspended.

Therefore, in the holding surface elevation step, among the plurality of thickness values T_{A}, T_{D}, T_{C}, T_{E}, and T_{B} measured in the thickness measurement step, the region (the measuring point E) where the thickness exceeds the preset target thickness S is locally heated by the spot heater 163. As a result, the porous member 11 (chuck table 10) is thermally expanded via the preliminarily ground wafer W, thereby locally elevating the holding surface 10a in a ring shape through the wafer W (see FIG. 25).

### 5) Finishing Grinding Step

In the second grinding method, after the holding surface elevation step is performed, the finish grinding step is performed. The finish grinding step is performed in the same manner as the preliminary grinding step, such that the grinding of the wafer W, which was temporarily suspended, is resumed. As shown in FIG. 21, in the finish grinding step, the preliminarily ground wafer W is ground to the finished thickness while the holding surface 10a remains elevated in the ring shape as established during the holding surface elevation step.

### 6) Unloading Step

In the second grinding method, after the finish grinding step is performed, the unloading step is performed. The unloading step is performed in the same manner as the unloading step in the first grinding method so that the wafer W is removed from the chuck table 10 (see FIG. 22).

Also with the second grinding method, as with the first grinding method, the in-plane thickness variation of the wafer W may be suppressed, allowing the wafer W to be ground to a uniform thickness over its entire surface. In the second grinding method, the preliminary grinding step and the finish grinding step for grinding the back surface WB of the wafer W, and the thickness measurement step and the holding surface elevation step may be performed at different timings.

### Third Grinding Method

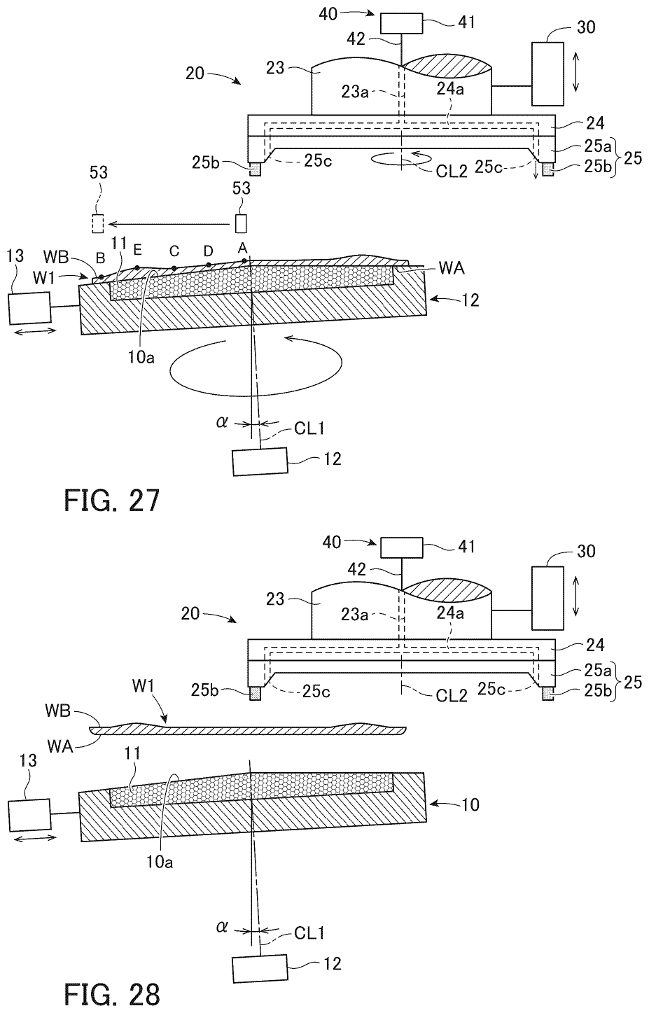

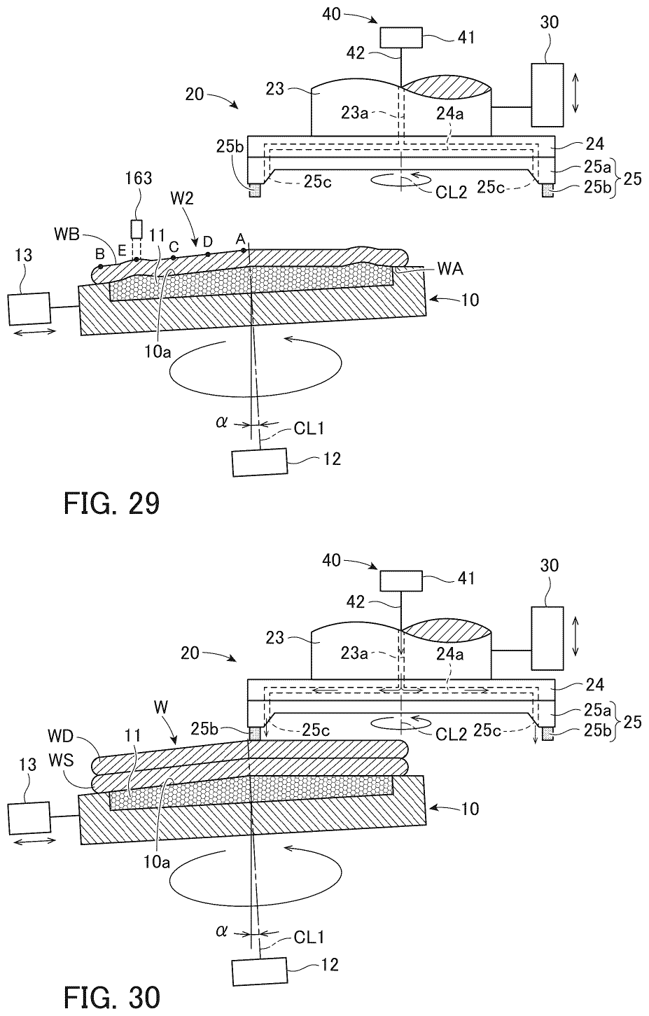

Next, a third method for grinding the wafer W will be described below. In the third grinding method of the wafer W according to the present embodiment, at least two wafers W are used: a first wafer W1 (see FIG. 27) is ground first, and its thickness is measured. After elevating the holding surface 10a based on the measurement result, a second wafer W2 (see FIG. 29) is subsequently ground.

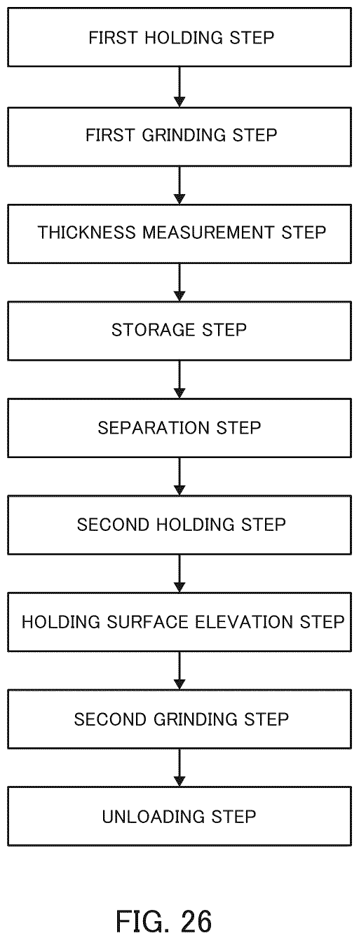

FIG. 26 is a flow diagram showing steps in the third grinding method. As shown in FIG. 26, the third grinding method is a method for grinding the wafer W through the following steps: (1) a first holding step, (2) a first grinding step, (3) a thickness measurement step, (4) a storage step, (5) a separation step, (6) a second holding step, (7) a holding surface elevation step, (8) a second grinding step, and (9) an unloading step. These steps will be described below. FIG. 27 is an explanatory view of the thickness measurement step in the third grinding method. FIG. 28 is an explanatory view of the separation step in the third grinding method. FIG. 29 is an explanatory view of the holding surface elevation step in the third grinding method.

### 1) First Holding Step

The first holding step in the third grinding method is performed in the same manner as the holding step in the first grinding method so that the first wafer W1 is held on the holding surface 10a (see FIG. 15).

### 2) First Grinding Step

In the third grinding method, after the holding step is performed, the first grinding step is performed. The first grinding step is performed in the same manner as the processing step of the first grinding method, except that the steps concurrently performed with the processing step are not performed. In the first grinding step, the first wafer W1 is ground to the preset finished thickness, and thereafter, as shown in FIG. 27, the grinding unit 20 is elevated by driving the elevating mechanism 30 to a position where no grinding is performed.

### 3) Thickness Measurement Step

In the third grinding method, after the first grinding step is performed, the thickness measurement step is performed. The thickness measurement step is performed in the same manner as the thickness measurement step of the first grinding method, except that grinding is not performed concurrently. In this thickness measurement step, thickness of the first wafer W1, which has been ground in the first grinding step, is measured at a plurality of positions (for example, the above-mentioned five points) by the thickness sensor 53 of the thickness measuring instrument 50 (see FIG. 27).

### 4) Storage Step:

In the third grinding method, after the thickness measurement step is performed, the storage step is performed. The storage step is performed in the same manner as the calculation step in the first grinding method. In this storage step, among the multiple thickness values T_{A}, T_{D}, T_{C}, T_{E}, and T_{B} measured in the thickness measurement step, the position(s) where the thickness exceeds the finished thickness (e.g., measurement point E; see FIG. 18B) is stored.

### 5) Separation Step

In the third grinding method, after the storage step is performed, the separation step is performed. The separation step is performed in the same manner as the unloading step in the first grinding method so that the first wafer W1 is separated and unloaded from the holding surface 10a of the chuck table 10 (see FIG. 28).

### 6) Second Holding Step

In the third grinding method, the second holding step is performed in the same manner as the first holding step, except that the wafer to be held is different. In this second holding step, the second wafer W2 is held on the holding surface 10a (see FIG. 15).

### 7) Holding Surface Elevation Step

In the third grinding method, after the second holding step is performed, the holding surface elevation step is performed. This holding surface elevation step is performed in the same manner as the spot heater positioning step and the holding surface elevation step of the first grinding method, except that this holding surface elevation step is performed with the second wafer W2, which has not yet been ground, held on the chuck table 10. Accordingly, as shown in FIG. 29, in the holding surface elevation step, the second wafer W2 is locally heated by the spot heater 163 at the measurement point E, where the thickness is greater than the finished thickness stored in the storage step. As a result, the porous member 11 (chuck table 10) is thermally expanded through the second wafer W2, and the holding surface 10a is locally elevated in a ring-shaped manner through the second wafer W2.

### 8) Second Grinding Step

In the third grinding method, after the holding surface elevation step, or concurrently with the execution of the holding surface elevation step, the second grinding step is performed. This second grinding step is performed in the same manner as the first grinding step, except that the wafer to be ground is replaced with the second wafer W2. In the second grinding step, the second wafer W2 is ground to the preset finished thickness while the holding surface 10a is elevated in a ring-shaped manner as adjusted in the holding surface elevation step (see FIG. 21).

### 9) Unloading Step

In the third grinding method, after the second grinding step is performed, the unloading step is performed. This unloading step is performed in the same manner as the unloading step in the first grinding method so that the second wafer W2 is unloaded from the chuck table 10 (see FIG. 22).

According to the third grinding method described above, similarly to the first and second grinding methods, the in-plane thickness variation of the second wafer W2 may be suppressed and the wafer W may be ground to a uniform thickness over the entire surface. In the third grinding method, for example, the first wafer W1 may be ground as a dummy wafer, and at least one second wafer W2 thereafter may be ground without measuring the thickness.

Note that embodiment of the present disclosure may not necessarily be limited to the configuration described above but may be modified in various ways. In the embodiments described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

In the above-described second embodiment, the case has been explained in which only the thickness value at the measurement point E becomes greater than the other thickness values in each of the wafers W, W1. However, variations in thickness that occur in the wafers W, W1 are not particularly limited. Therefore, each of the above-described grinding methods may be performed even when the thickness is non-uniform such that the thickness values become greater or smaller at a plurality of positions of each of the wafers W, W1.

For example, the wafer W in the second embodiment may be replaced with a bonded wafer, as shown in FIG. 30, in which two wafers are bonded with a bonding member (not shown). The bonded wafer replacing the wafer W is formed of a support wafer WS located on the lower side in FIG. 30 and a device wafer WD located on the upper side in FIG. 30 bonded to an upper surface of the support wafer WS with the bonding member (adhesive). On a bonding surface (the lower surface in FIG. 30) of the device wafer WD to be bonded to the support wafer WS, unillustrated devices are formed. When the wafer W being this bonded wafer is ground using any of the above-described grinding methods, in the respective holding step, the lower surface of the support wafer WS is held by suction on the holding surface 10a of the chuck table 10, and in the respective grinding step, the device wafer WD is ground. While grinding, a ring-shaped thickness variation may occur in the bonding member. As a result, when the lower surface of the support wafer WS is held by suction on the holding surface 10a of the chuck table 10, the upper surface of the device wafer WD may become uneven. However, even if the upper surface of the device wafer WD being uneven due to the bonding member (adhesive) in the wafer W being the bonded wafer, the thickness of the device wafer WD after grinding may be equalized by performing the first through third grinding methods described above.

For another example, in the embodiments above, the thickness measuring device 50 having the thickness sensor 53 mounted at the tip of the arm 52 that horizontally pivots about the support shaft 51 is used; however, a configuration in which thickness sensors are mounted at five points on a horizontal arm that does not pivot may be used optionally.

For another example, in the above embodiments, the grinding unit 20 is moved up or down by the elevating mechanism 30. However, it is only necessary to move the chuck table 10 and the grinding unit 20 relative to each other in the vertical direction. Therefore, the elevating mechanism 30 may be configured to move both the chuck table 10 and the grinding unit 20, or solely the chuck table 10.

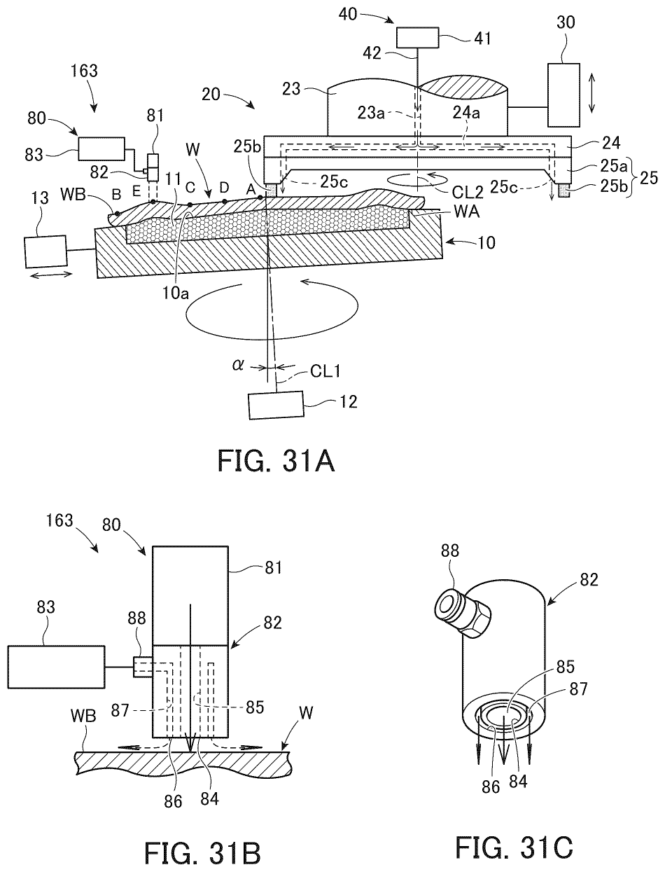

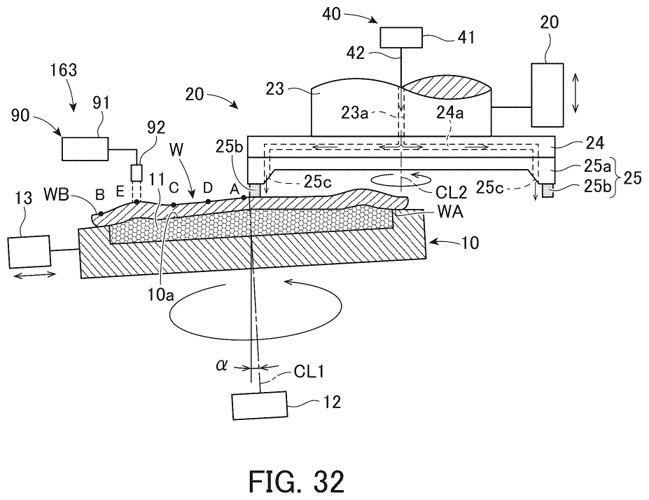

For another example, the spot heater 163 may be configured such that the heater unit is replaced with an emitting mechanism 80, as shown in FIGS. 31A-31C, which may emit light having a wavelength absorbable by the wafer W, or with an injection mechanism 90, as shown in FIG. 32, which may blow hot air onto the wafer W. FIG. 31A is a schematic view of the grinding apparatus, partially vertically cross-sectioned, according to a first modified example, FIG. 31B is a partially enlarged view of the grinding apparatus shown in FIG. 31A, and FIG. 31C is a schematic perspective view showing the nozzle of the first modified example as viewed from below.

As shown in FIG. 31A, the emitting mechanism 80 in the first modified example includes a light source 81, a nozzle 82, and an air source 83.

The light emitted from the light source 81 is set to a wavelength capable of locally heating the wafer W. Examples of such light include a laser beam, visible light such as red light, far-infrared ray, and near-infrared ray. When the emitting mechanism 80 emits a laser beam, the light source 81 converges the laser beam oscillated by an oscillator housed inside a casing, and the converged laser beam is emitted from the nozzle 82.

As shown in FIGS. 31B and 31C, the nozzle 82 disposed below the light source 81 and is formed in a double-walled cylindrical shape. The nozzle 82 includes an optical path 85, which is formed at a central position parallel to the vertical direction (Z-axis direction) and has its lower end serving as a light transmission opening 84, and an air flow path 87, which is formed at a position surrounding the optical path 85 and has its lower end serving as an air discharge opening 86. The air flow path 87 is connected to an air source 83 via an air supply port 88.

In the nozzle 82, the light emitted from the light source 81 passes through the optical path 85 and is emitted vertically downward (−Z direction) onto the wafer W from the light transmission opening 84. In addition, in the nozzle 82, air supplied from the air source 83 passes through the air flow path 87 and is discharged vertically downward onto the wafer W from the air discharge opening 86.

The emitting mechanism 80 is configured to locally heat the wafer W by emitting light onto the wafer W held on the lower side of the holding surface 10a, thereby thermally expanding the porous member 11 of the chuck table 10 via the wafer W and enabling a change in the height of the holding surface 10a. In addition, the emitting mechanism 80 is configured to emit air from the air discharge opening 86 at a position surrounding the emitted light simultaneously with the light emission onto the wafer W. This air discharge may prevent the grinding water flowing over the wafer W from entering the light irradiation area on the wafer W. As a result, the wafer W may be effectively heated by the light emitted from the emitting mechanism 80.

FIG. 32 is a schematic view of part of the grinding apparatus, partially vertically cross-sectioned, according to a second modified example. As shown in FIG. 32, the injection mechanism 90 in the second modified example includes a hot air source 91 and a nozzle 92. The hot air source 91 is configured to heat air and generate a hot air flow, and may be, for example, a heating mechanism such as an electric heating wire and an air-blowing mechanism such as a fan. The nozzle 92 is configured to emit the hot air generated by the hot air source 91 onto the wafer W in the vertically downward direction (−Z direction).

The injection mechanism 90 is configured to locally heat the wafer W by blowing the hot air onto the lower wafer W held on the holding surface 10a, thereby expanding the porous member 11 of the chuck table 10 through the wafer W, and enabling the height of the holding surface 10a to be changed. In other words, the hot air blown from the injection mechanism 90 refers to air at a temperature capable of changing the height of the holding surface 10a by heating the wafer W and thereby causing expansion of the porous member 11.

In the above-described embodiments, infeed grinding is described, in which the lower surfaces of the grinding stones 25b are brought into contact with a radial portion of the wafer W to grind the wafer W. However, the grinding method is not limited to this. The wafer W may be ground by creep-feed grinding, in which the grinding stones 25b and the chuck table 10 holding the wafer W are moved relative to each other in a horizontal direction so that the wafer W is ground by the side surfaces of the grinding stones 25b. For measuring the thickness of the wafer W ground by the creep-feed grinding, instead of measuring the thickness at points in a radial portion of the wafer W, thicknesses may be measured at a plurality of positions in a direction of relative movement of the wafer W with respect to the grinding stones 25b, i.e., a diameter direction, and at a plurality of positions in a direction orthogonal to the diameter direction. Furthermore, by spraying warm water or cold water from the spray nozzle 60, linear portions of the holding surface 10a may be caused to thermally expand or contract.

1. A grinding apparatus for grinding a wafer, comprising:
a chuck table configured to hold the wafer on a holding surface thereof;
a grinding unit configured to grind the wafer by rotating an annular array of grinding stones about a grinding stone rotation axis extending through a center of the annular array of grinding stones;
an elevating mechanism configured to elevate and lower the chuck table and the grinding unit relative to each other;
a grinding water supply device configured to supply grinding water to an area where the grinding stones contact the wafer;
a spray nozzle configured to spray warm water or cold water from above the holding surface onto at least a part of the holding surface or a part of the wafer held on the holding surface;
a thickness measuring device configured to measure thicknesses at a plurality of positions in the wafer held on the holding surface; and
a controller configured to control spraying water from the spray nozzle toward the wafer so as to expand or contract the chuck table via the wafer and thereby changing a height of the holding surface such that:
warm water is sprayed toward a position, of which thickness value among a plurality of thickness values measured at the plurality of positions by the thickness measuring device indicates a thickness greater than a preset target thickness, or a position, of which thickness value indicates a thickness greater than an average value of the plurality of thickness values; or
cold water is sprayed toward a position, of which thickness value indicates a thickness less than the preset target thickness, or a position, of which thickness value indicates a thickness less than the average value of the plurality of thickness values.

2. A wafer grinding method performed using the grinding apparatus according to claim 1, comprising:
holding the wafer on the holding surface of the chuck table; and
grinding the wafer to a preset finished thickness by rotating the chuck table about a table rotation axis extending through a center of the holding surface, the grinding including:
measuring thicknesses at the plurality of positions in a radial portion of the wafer by the thickness measuring device while grinding the wafer with the grinding stones, and
spraying warm water toward the position, of which thickness value among the plurality of thickness values measured at the plurality of positions by the thickness measuring device indicates the thickness greater than the preset target thickness, or the position, of which thickness value indicates the thickness greater than the average value of the plurality of thickness values; or
spraying cold water toward the position, of which thickness value indicates the thickness less than the preset target thickness, or the position, of which thickness value indicates the thickness less than the average value of the plurality of thickness values.

3. A wafer grinding method performed using the grinding apparatus according to claim 1, comprising:
holding the wafer on the holding surface of the chuck table;
a preliminary grinding including grinding the wafer to a thickness that does not reach a preset finished thickness;
measuring thicknesses at a plurality of positions in the wafer preliminarily ground during the preliminary grinding by the thickness measuring device;
changing the height of the holding surface by causing the chuck table to expand or contract via the preliminarily ground wafer, by:
spraying warm water from the spray nozzle toward a position, of which thickness value among a plurality of thickness values measured during the thickness measurement indicates a thickness greater than the preset target thickness, or a position, of which thickness value indicates a thickness greater than an average value of the plurality of thickness values measured during the thickness measurement, or
spraying cold water from the spray nozzle toward a position, of which thickness value among the plurality of thickness values measured during the thickness measurement indicates a thickness less than the preset target thickness, or a position, of which thickness value indicates a thickness less than the average value of the plurality of thickness values measured during the thickness measurement; and
a finish grinding including grinding the preliminarily ground wafer to the preset finished thickness.

4. A wafer grinding method performed using the grinding apparatus according to claim 1, comprising:
a first holding including holding a first wafer on the holding surface of the chuck table;
a first grinding including griding the first wafer to a preset finished thickness;
measuring thicknesses at a plurality of positions in the first wafer ground during the first grinding by the thickness measuring device;
storing a first position, of which thickness value among a plurality of thickness values measured during the thickness measurement indicates a thickness greater than the finished thickness, and a second position, of which thickness value among the plurality of thickness values measured during the thickness measurement indicates a thickness less than the finished thickness, in the controller;
separating the first wafer from the holding surface of the chuck table;
a second holding including holding a second wafer on the holding surface of the chuck table;
correcting the height of the holding surface via the second wafer by spraying warm water from the spray nozzle toward the first position in the second wafer as stored in the controller or spraying cold water from the spray nozzle toward the second position in the second wafer as stored in the controller; and
a second grinding including grinding the second wafer to the finished thickness after or during the holding surface height correction.

5. The wafer grinding method according to claim 2,
wherein the wafer is a bonded wafer including a support wafer and a device wafer having a bonding surface on which devices are formed and which is bonded to the support wafer,
wherein, during the holding, the first holding, or the second holding, the chuck table holds the support wafer thereon by suction, and
wherein the grinding, the preliminary grinding, the finish grinding, the first grinding, or the second grinding includes grinding the device wafer.

6. A grinding apparatus for grinding a wafer, comprising:
a chuck table configured to hold the wafer on a holding surface thereof;
a grinding unit configured to grind the wafer by rotating an annular array of grinding stones about a grinding stone rotation axis extending through a center of the annular array of grinding stones;
an elevating mechanism configured to elevate and lower the chuck table and the grinding unit relative to each other;
a grinding water supply device configured to supply grinding water to an area where the grinding stones contact the wafer;
a thickness measuring device configured to measure thicknesses at a plurality of positions in the wafer held on the holding surface;
a spot heater configured to locally heat the wafer held on the holding surface; and
a holding surface height change controller configured to control the spot heater to heat the wafer at a position, of which thickness value among a plurality of thickness values measured at the plurality of positions by the thickness measuring device indicates a thickness greater than a preset target thickness, or a position, of which thickness value indicates a thickness greater than an average value of the plurality of thickness values, thereby causing the chuck table to locally expand via the wafer and elevating the holding surface.

7. The grinding apparatus according to claim 6, wherein the spot heater includes a mechanism configured to blow hot air onto the wafer.

8. The grinding apparatus according to claim 6, wherein the spot heater includes a mechanism configured to emit light having a wavelength absorbable by the wafer toward the wafer.

9. A wafer grinding method using the grinding apparatus according to claim 6, comprising:
holding the wafer on the holding surface; and
grinding the wafer to a preset finished thickness by rotating the chuck table about a table rotation axis extending through a center of the holding surface, the grinding including:
measuring thicknesses at the plurality of positions in the wafer by the thickness measuring device while grinding the wafer with the grinding stones, and
while measuring, heating the wafer locally by the spot heater at the position, of which thickness value among the plurality of thickness values measured at the plurality of positions by the thickness measuring device indicates the thickness greater than the preset target thickness, the preset target thickness being thicker than the preset finished thickness, or the position, of which thickness value indicates the thickness greater than the average value of the plurality of thickness values, thereby elevating the holding surface locally via the wafer.

10. A wafer grinding method performed using the grinding apparatus according to claim 6, comprising:
holding the wafer on the holding surface;
a preliminary grinding including grinding the wafer preliminarily to the preset target thickness which does not reach a preset finished thickness;
measuring thicknesses at a plurality of positions in the wafer preliminarily ground by the thickness measuring device;
heating the preliminarily ground wafer locally with the spot heater at the position, of which thickness value among the plurality of thickness values measured during the thickness measurement indicates the thickness greater than the target thickness, or the position, of which thickness value indicates the thickness greater than the average value of the plurality of thickness values, thereby causing the chuck table to locally expand via the preliminarily ground wafer and elevating the holding surface locally via the wafer; and
a finish grinding including grinding the preliminarily ground wafer to the finished thickness after or during the holding surface elevation.

11. A wafer grinding method performed using the grinding apparatus according to claim 6, comprising:
a first holding including holding a first wafer on the holding surface;
a first grinding including griding the first wafer to a preset finished thickness;
measuring thicknesses at a plurality of positions in the first wafer ground during the first grinding by the thickness measuring device;
storing a position, of which thickness value among a plurality of thickness values measured at the plurality of positions during the thickness measurement indicates a thickness greater than the finished thickness;
separating the first wafer from the holding surface;
a second holding including holding a second wafer on the holding surface;
heating the second wafer locally with the spot heater at the position in the second wafer as stored in the storage, thereby elevating the holding surface locally via the second wafer; and
a second griding including grinding the second wafer to the preset finished thickness after or during the holding surface elevation.

12. The wafer grinding method according to claim 9,
wherein the wafer is a bonded wafer including a support wafer and a device wafer having a bonding surface on which devices are formed and which is bonded to the support wafer;
wherein, during the holding, the first holding, or the second holding, the holding surface of the chuck table holds the support wafer thereon by suction, and
wherein the grinding, the preliminary grinding, the finish grinding, the first grinding, or the second grinding includes grinding the device wafer.
